(19) United States
(12) Patent Application Publication
(10) Pub. No.: US 2023/0367052 A1
(43) Pub. Date: Nov. 16, 2023

(54) COLORING COMPOSITION, FILM, COLOR FILTER AND SOLID-STATE IMAGING ELEMENT

(71) Applicant: FUJIFILM Corporation, Tokyo (JP)

(72) Inventor: Takahiro OYA, Shizuoka (JP)

(73) Assignee: FUJIFILM Corporation, Tokyo (JP)

(21) Appl. No.: 18/361,216

(22) Filed: Jul. 28, 2023

Related U.S. Application Data
(63) Continuation of application No. PCT/JP2022/002606, filed on Jan. 25, 2022.

(30) Foreign Application Priority Data
Feb. 25, 2021 (JP) 2021-028037

(51) Int. Cl. G02B 5/22; C09D 7/41; C09D 7/20; C09B 23/01

(52) U.S. Cl. CPC G02B 5/223; C09B 23/0075; C09D 7/20; C09D 7/41

(57) ABSTRACT

Provided is a coloring composition containing a colorant, a resin, a polymerizable compound, a photopolymerization initiator, an ultraviolet absorber, and a solvent, in which the colorant contains an unsubstituted copper phthalocyanine pigment and a halogenated copper phthalocyanine pigment, a content of the unsubstituted copper phthalocyanine pigment in a total mass of the colorant is 10% by mass or more, and a content of the halogenated copper phthalocyanine pigment in the total mass of the colorant is 40% by mass or more.

### CROSS-REFERENCE TO RELATED APPLICATIONS

This application is a continuation application of International Application No. PCT/JP2022/002606, filed Jan. 25, 2022, the disclosure of which is incorporated herein by reference in its entirety. Further, this application claims priority from Japanese Pat. Application No. 2021-028037, filed Feb. 25, 2021, the disclosure of which is incorporated herein by reference in its entirety.

### BACKGROUND OF THE INVENTION

### 1. Field of the Invention

The present invention relates to a coloring composition containing a colorant. The present invention further relates to a film formed of the coloring composition, a color filter, and a solid-state imaging element.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

JP2008-052239A discloses a cyan coloring composition for a color filter, containing a phthalocyanine-based blue pigment including either one or both of Color Index Pigment Blue 15:3 and Color Index Pigment Blue 15:4, a phthalocyanine-based green pigment including Color Index Pigment Green 7, a resin, a polymerizable compound, and a photopolymerization initiator.

### SUMMARY OF THE INVENTION

In a case where a pixel is formed by a photolithography method using a coloring composition containing a colorant, a polymerizable compound, and a photopolymerization initiator, a composition layer formed by applying the coloring composition onto a support is exposed through a mask having a pattern, and a non-exposed portion is removed by development to form the pixel.

As a result of intensive studies on a coloring composition for forming a cyan pixel, the present inventor has found that increasing illuminance during exposure tends to increase a line width of the pixel to be obtained. Therefore, it has been found that the coloring composition for forming a cyan pixel has a large illuminance dependence of the line width of the pixel to be obtained.

In addition, in forming a pixel using a coloring composition, the pixel may be formed of a coloring composition which has been stored at a low temperature for a long period of time. In a case where sensitivity of the coloring composition is lowered during storage, the line width of the pixel to be obtained is likely to differ even in a case where the pixel is formed under the same exposure conditions as those of the coloring composition before storage. Therefore, it is desired that the coloring composition is excellent in temporal stability of sensitivity.

As a result of studies on the coloring composition disclosed in JP2008-052239A, the present inventor has found that, with the coloring composition, the line width of the pixel to be obtained also has a large illuminance dependence.

Therefore, an object of the present invention is to provide a coloring composition in which a line width of a pixel to be obtained has a small illuminance dependence and temporal stability of sensitivity is excellent. Another object of the present invention is to provide a film, a color filter, and a solid-state imaging element.

According to the studies conducted by the present inventor, it has been found that the above-described objects can be achieved by a coloring composition described below, thereby leading to the completion of the present invention. Therefore, the present invention provides the following.

<1> A coloring composition comprising:
a colorant;
a resin;
a polymerizable compound;
a photopolymerization initiator;
an ultraviolet absorber; and
a solvent,
in which the colorant contains an unsubstituted copper phthalocyanine pigment and a halogenated copper phthalocyanine pigment,
a content of the unsubstituted copper phthalocyanine pigment in a total mass of the colorant is 10% by mass or more, and
a content of the halogenated copper phthalocyanine pigment in the total mass of the colorant is 40% by mass or more.

<2> The coloring composition according to <1>,
in which the unsubstituted copper phthalocyanine pigment includes Color Index Pigment Blue 15:4, and
the halogenated copper phthalocyanine pigment includes Color Index Pigment Green 7.

<3> The coloring composition according to <1> or <2>,

in which a total content of the unsubstituted copper phthalocyanine pigment and the halogenated copper phthalocyanine pigment in the total mass of the colorant is 70% to 100% by mass.

<4> The coloring composition according to any one of <1> to <3>,

in which, in a case where a film having a film thickness of 0.6 µm is formed of the coloring composition, an average value of transmittance of light in a wavelength range of 400 to 450 nm in a thickness direction of the film is 75% or more, an average value of transmittance of light in a wavelength range of 650 to 700 nm in the thickness direction of the film is 30% or less, and a wavelength at which a transmittance is 50% exists in a wavelength range of 560 to 590 nm.

<5> A coloring composition comprising:
a colorant;
a resin;
a polymerizable compound;
a photopolymerization initiator;
an ultraviolet absorber; and
a solvent,
in which, in a case where a film having a film thickness of 0.6 µm is formed of the coloring composition, an average value of transmittance of light in a wavelength range of 400 to 450 nm in a thickness direction of the film is 75% or more, an average value of transmittance of light in a wavelength range of 650 to 700 nm in the thickness direction of the film is 30% or less, and a wavelength at which a transmittance is 50% exists in a wavelength range of 560 to 590 nm.

<6> The coloring composition according to any one of <1> to <5>,

in which a content of the ultraviolet absorber in a total solid content of the coloring composition is 0.5% by mass or more.

<7> The coloring composition according to any one of <1> to <6>,

in which, in the ultraviolet absorber, a value of a ratio of an absorbance A₂ at a wavelength of 410 nm to an absorbance A₁ at a wavelength of 365 nm is 0.06 or less.

<8> The coloring composition according to any one of <1> to <7>,

in which the ultraviolet absorber is at least one selected from a conjugated diene compound, a benzotriazole compound, a dibenzoyl compound, or a triazine compound.

<9> The coloring composition according to any one of <1> to <8>,

in which the coloring composition contains 100 to 350 parts by mass of the resin with respect to 100 parts by mass of the colorant.

<10> The coloring composition according to any one of <1> to <9>,
in which the resin includes a resin having at least one repeating unit selected from a repeating unit represented by Formula (1) or a repeating unit represented by Formula (2),

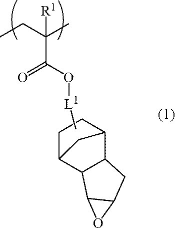

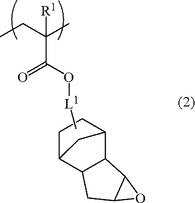

in the formulae, L¹ represents a single bond or a divalent linking group, and R¹ represents a hydrogen atom or a substituent.

<11> The coloring composition according to any one of <1> to <10>,
in which a content of Color Index Pigment Blue 15:4 in the total mass of the colorant is 10% to 50% by mass,
a content of the photopolymerization initiator in a total solid content of the coloring composition is 3% to 10% by mass, and
a content of the ultraviolet absorber in the total solid content of the coloring composition is 1% to 10% by mass.

<12> A film obtained from the coloring composition according to any one of <1> to <11>.

<13> A color filter comprising:

the film according to <12>.

<14> A solid-state imaging element comprising:

the film according to <12>.

According to the present invention, it is possible to provide a coloring composition in which a line width of a pixel to be obtained has a small illuminance dependence and temporal stability of sensitivity is excellent. In addition, according to the present invention, it is also possible to provide a film formed of the coloring composition, a color filter, and a solid-state imaging element.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a colorant which is hardly dissolved in a solvent.

In the present specification, the term “step” is not only an independent step, but also includes a step which is not clearly distinguished from other steps in a case where an intended action of the step is obtained.

### Coloring Composition

The coloring composition according to a first aspect of the present invention is a coloring composition containing a colorant, a resin, a polymerizable compound, a photopolymerization initiator, an ultraviolet absorber, and a solvent, in which the colorant contains an unsubstituted copper phthalocyanine pigment and a halogenated copper phthalocyanine pigment, a content of the unsubstituted copper phthalocyanine pigment in a total mass of the colorant is 10% by mass or more, and a content of the halogenated copper phthalocyanine pigment in the total mass of the colorant is 40% by mass or more.

In the coloring composition according to the first aspect, it is preferable that, in a case where a film having a film thickness of 0.6 µm is formed of the coloring composition, an average value of transmittance of light in a wavelength range of 400 to 450 nm in a thickness direction of the film is 75% or more, an average value of transmittance of light in a wavelength range of 650 to 700 nm in the thickness direction of the film is 30% or less, and a wavelength at which a transmittance is 50% exists in a wavelength range of 560 to 590 nm.

In addition, the coloring composition according to a second aspect of the present invention is a coloring composition containing a colorant, a resin, a polymerizable compound, a photopolymerization initiator, an ultraviolet absorber, and a solvent, in which, in a case where a film having a film thickness of 0.6 µm is formed of the coloring composition, an average value of transmittance of light in a wavelength range of 400 to 450 nm in a thickness direction of the film is 75% or more, an average value of transmittance of light in a wavelength range of 650 to 700 nm in the thickness direction of the film is 30% or less, and a wavelength at which a transmittance is 50% exists in a wavelength range of 560 to 590 nm.

Hereinafter, the coloring composition according to the first aspect and the coloring composition according to the second aspect are collectively referred to as a coloring composition according to the embodiment of the present invention. With the coloring composition according to the embodiment of the present invention, in a case where a pixel is formed by a photolithography method using the coloring composition, since a line width of the pixel to be obtained has a small illuminance dependence, variations in the line width of the pixel to be obtained can be suppressed even in a case where illuminance conditions during exposure are varied. In addition, the coloring composition according to the embodiment of the present invention is also excellent in temporal stability of sensitivity, and even in a case where the pixel is formed of a coloring composition after storage, the variations in the line width of the pixel to be obtained can be suppressed.

In a case where a film having a film thickness of 0.6 µm is formed of the coloring composition according to the embodiment of the present invention, an average value of transmittance of light in a wavelength range of 400 to 450 nm in a thickness direction of the film is preferably 80% or more, and more preferably 85% or more.

In addition, in a case where a film having a film thickness of 0.6 µm is formed of the coloring composition according to the embodiment of the present invention, an average value of transmittance of light in a wavelength range of 650 to 700 nm in the thickness direction of the film is preferably 25% or less, and more preferably 20% or less.

In addition, in a case where a film having a film thickness of 0.6 µm is formed of the coloring composition according to the embodiment of the present invention, a wavelength at which a transmittance is 50% preferably exists in a wavelength range of 565 to 585 nm, and more preferably exists in a wavelength range of 570 to 580 nm.

The coloring composition having such spectral characteristics is preferably used as a coloring composition for forming a cyan pixel.

The coloring composition according to the embodiment of the present invention is preferably used as a coloring composition for forming a color filter. More specifically, the coloring composition according to the embodiment of the present invention can be preferably used as a coloring composition for forming a pixel of a color filter, and can be more preferably used as a coloring composition for forming a cyan pixel of a color filter. In addition, the coloring composition according to the embodiment of the present invention is preferably used as a coloring composition for forming a color filter used in a solid-state imaging element. Hereinafter, the respective components used in the coloring composition according to the embodiment of the present invention will be described.

### <<Colorant>>

The coloring composition according to the embodiment of the present invention contains a colorant. It is preferable that the colorant contained in the coloring composition according to the embodiment of the present invention includes an unsubstituted copper phthalocyanine pigment and a halogenated copper phthalocyanine pigment.

Here, the copper phthalocyanine pigment is a phthalocyanine pigment having a copper atom as a central metal. That is, the copper phthalocyanine pigment is a pigment having a structure in which a phthalocyanine compound which is a ligand is coordinated with a copper atom which is a central metal. In addition, the unsubstituted copper phthalocyanine pigment is a pigment in which the phthalocyanine compound as a ligand is an unsubstituted phthalocyanine compound, that is, phthalocyanine. In addition, the halogenated copper phthalocyanine pigment is a pigment having a structure in which the phthalocyanine compound as a ligand is a phthalocyanine compound having a halogen atom as a substituent.

Examples of the unsubstituted copper phthalocyanine pigment include a compound represented by Formula (Pc-1). In addition, examples of the halogenated copper phthalocyanine pigment include a compound represented by Formula (Pc-2).

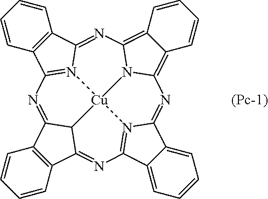

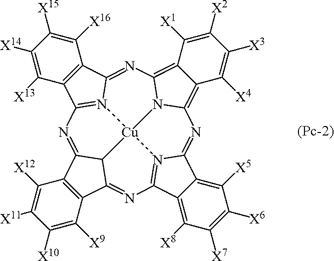

In Formula (Pc-2), X¹ to X¹⁶ represent a hydrogen atom or a halogen atom, and at least one of X¹, ..., or X¹⁶ represents a halogen atom. Examples of the halogen atom represented by X¹ to X¹⁶ include a fluorine atom, a chlorine atom, a bromine atom, and an iodine atom, and a chlorine atom or a bromine atom is preferable. It is preferable that 4 to 16 of X¹ to X¹⁶ are halogen atoms, it is more preferable that 8 to 16 thereof are halogen atoms, it is still more preferable that 12 to 16 thereof are halogen atoms, and it is particularly preferable that all of X¹ to X¹⁶ are halogen atoms.

Specific examples of the unsubstituted copper phthalocyanine pigment include Color Index (C. I.) Pigment Blue 15, 15:1, 15:2, 15:3, 15:4, and 15:6. From the reason that it is possible to form a pixel having excellent spectral characteristics suitable for cyan and other colors, it is preferable that the unsubstituted copper phthalocyanine pigment includes C. I. Pigment Blue 15:4. The unsubstituted copper phthalocyanine pigment may be used alone or in combination of two or more kinds thereof. A content of the C. I. Pigment Blue 15:4 in the total mass of the unsubstituted copper phthalocyanine pigment is preferably 90% to 100% by mass, more preferably 95% to 100% by mass, and still more preferably 99% to 100% by mass. It is particularly preferable that the unsubstituted copper phthalocyanine pigment is only the C. I. Pigment Blue 15:4.

Specific examples of the halogenated copper phthalocyanine pigment include C. I. Pigment Green 7 and 36. From the reason that it is easy to form a pixel having excellent spectral characteristics suitable for cyan and other colors, it is preferable that the halogenated copper phthalocyanine pigment includes C. I. Pigment Green 7. The halogenated copper phthalocyanine pigment may be used alone or in combination of two or more kinds thereof. Examples of a preferred aspect of the halogenated copper phthalocyanine pigment include the following aspect 1 and aspect 2. In a case of the aspect 1, it is possible to form a pixel having more excellent spectral characteristics. In a case of the aspect 2, it is possible to further improve light resistance of the film to be obtained.

Aspect 1: aspect in which the halogenated copper phthalocyanine pigment is only the C. I. Pigment Green 7

Aspect 2: aspect in which the halogenated copper phthalocyanine pigment includes C. I. Pigment Green 7 and C. I. Pigment Green 36

In the above-described aspect 2, a proportion of C. I. Pigment Green 7 and C. I. Pigment Green 36 is preferably 10 to 50 parts by mass of C. I. Pigment Green 36 with respect to 100 parts by mass of C. I. Pigment Green 7. The upper limit is preferably 45 parts by mass or less and more preferably 40 parts by mass or less. The lower limit is preferably 15 parts by mass or more and more preferably 20 parts by mass or more. In addition, the total content of C. I. Pigment Green 7 and C. I. Pigment Green 36 in the total mass of the halogenated copper phthalocyanine pigment is preferably 90% to 100% by mass, more preferably 95% to 100% by mass, and still more preferably 99% to 100% by mass.

The coloring composition according to the embodiment of the present invention may contain a colorant (hereinafter, other colorants) other than the unsubstituted copper phthalocyanine pigment and the halogenated copper phthalocyanine pigment. A content of the other colorants in the colorant is preferably 20% by mass or less, more preferably 10% by mass or less, and still more preferably 5% by mass or less, and from the viewpoint of color separation, it is particularly preferable that the colorant does not substantially contain the other colorants. The case where the colorant used in the coloring composition according to the embodiment of the present invention does not substantially contain the other colorants means that the content of the other colorants in the colorant is less than 0.5% by mass, preferably less than 0.1% by mass and more preferably 0% by mass.

Examples of the other colorants include chromatic colorants such as a yellow colorant, a green colorant, a red colorant, a blue colorant, a violet colorant, and an orange colorant. The other colorants may be either a pigment or a dye. The pigment and the dye may be used in combination. Examples of the pigment include the following pigments.
C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232, 233, 234, 235, 236, and the like (all of which are yellow pigments);
C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);
C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, 297, and the like (all of which are red pigments);
C. I. Pigment Green 58, 59, 62, 63, 64, 65, 66, and the like (all of which are green pigments);
C. I. Pigment Violet 1, 19, 23, 27, 32, 37, 42, 60, 61, and the like (all of which are violet pigments); and
C. I. Pigment Blue 1, 2, 16, 22, 29, 60, 64, 66, 79, 80, 87, 88, and the like (all of which are blue pigments).

A content of the colorant in the total solid content of the coloring composition is preferably 20% to 70% by mass. The upper limit is preferably 67% by mass or less and more preferably 64% by mass or less. The lower limit is preferably 22% by mass or more and more preferably 25% by mass or more.

In addition, the content of the unsubstituted copper phthalocyanine pigment in the total mass of the colorant is preferably 10% by mass or more, more preferably 12% by mass or more, and still more preferably 15% by mass or more. The upper limit is preferably 60% by mass or less, more preferably 55% by mass or less, and still more preferably 50% by mass or less.

In addition, the content of the halogenated copper phthalocyanine pigment in the total mass of the colorant is preferably 40% by mass or more, more preferably 45% by mass or more, and still more preferably 50% by mass or more. The upper limit is preferably 85% by mass or less, more preferably 75% by mass or less, and still more preferably 65% by mass or less.

In addition, the total content of the unsubstituted copper phthalocyanine pigment and the halogenated copper phthalocyanine pigment in the total mass of the colorant is preferably 70% to 100% by mass, more preferably 80% to 100% by mass, and still more preferably 85% to 100% by mass.

In addition, a proportion of the unsubstituted copper phthalocyanine pigment and the halogenated copper phthalocyanine pigment in the colorant is preferably 120 to 600 parts by mass of the halogenated copper phthalocyanine pigment, more preferably 140 to 400 parts by mass thereof, and still more preferably 160 to 200 parts by mass thereof with respect to 100 parts by mass of the unsubstituted copper phthalocyanine pigment.

In addition, the content of C. I. Pigment Blue 15:4 in the total mass of the colorant is preferably 10% by mass or more, more preferably 12% by mass or more, and still more preferably 15% by mass or more. The upper limit is preferably 60% by mass or less, more preferably 55% by mass or less, and still more preferably 50% by mass or less.

In addition, the content of C. I. Pigment Green 7 in the total mass of the colorant is preferably 40% by mass or more, more preferably 45% by mass or more, and still more preferably 50% by mass or more. The upper limit is preferably 80% by mass or less, more preferably 70% by mass or less, and still more preferably 62% by mass or less.

In addition, the total content of C. I. Pigment Blue 15:4 and C. I. Pigment Green 7 in the total mass of the colorant is preferably 75% to 100% by mass, more preferably 80% to 100% by mass, and still more preferably 85% to 100% by mass.

In addition, a proportion of C. I. Pigment Blue 15:4 and C. I. Pigment Green 7 in the colorant is preferably 120 to 500 parts by mass of C. I. Pigment Green 7, more preferably 140 to 400 parts by mass thereof, and still more preferably 160 to 300 parts by mass thereof with respect to 100 parts by mass of C. I. Pigment Blue 15:4.

In addition, the content of the unsubstituted copper phthalocyanine pigment in the total solid content of the coloring composition is preferably 10% to 50% by mass. The upper limit is preferably 45% by mass or less, more preferably 40% by mass or less, and still more preferably 35% by mass or less. The lower limit is preferably 12% by mass or more, more preferably 14% by mass or more, and still more preferably 16% by mass or more.

In addition, the content of C. I. Pigment Blue 15:4 in the total solid content of the coloring composition is preferably 10% to 50% by mass. The upper limit is preferably 45% by mass or less, more preferably 40% by mass or less, and still more preferably 35% by mass or less. The lower limit is preferably 12% by mass or more, more preferably 14% by mass or more, and still more preferably 16% by mass or more.

### <<Resin>>

The coloring composition according to the embodiment of the present invention contains a resin. The resin is blended in, for example, an application for dispersing a pigment or the like in the coloring composition or an application as a binder. Mainly, a resin which is used for dispersing a pigment or the like in the coloring composition is also referred to as a dispersant. However, such applications of the resin are merely exemplary, and the resin can also be used for other purposes in addition to such applications.

A weight-average molecular weight (Mw) of the resin is preferably 3,000 to 2,000,000. The upper limit is preferably 1,000,000 or less and more preferably 500,000 or less. The lower limit is preferably 4,000 or more and more preferably 5,000 or more.

Examples of the resin include a (meth)acrylic resin, an epoxy resin, a (meth)acrylamide resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, and a siloxane resin. In addition, as the resin, resins described in Examples of WO2016/088645A, resins described in JP2017-057265A, resins described in JP2017-032685A, resins described in JP2017-075248A, resins described in JP2017-066240A, resins described in JP2017-167513A, resins described in JP2017-173787A, resins described in paragraph Nos. 0041 to 0060 of JP2017-206689A, resins paragraph Nos. 0022 to 0071 of JP2018-010856A, block polyisocyanate resins described in JP2016-222891A, resins described in JP2020-122052A, resins described in JP2020-111656A, resins described in JP2020-139021A, and resins including a constitutional unit having a ring structure in the main chain and a constitutional unit having a biphenyl group in the side chain, which are described in JP2017-138503A, can also be used.

As the resin, it is preferable to use a resin having an acid group. Examples of the acid group include a carboxy group, a phosphoric acid group, a sulfo group, and a phenolic hydroxy group.

An acid value of the resin having an acid group is preferably 30 to 500 mgKOH/g. The lower limit is more preferably 40 mgKOH/g or more and particularly preferably 50 mgKOH/g or more. The upper limit is more preferably 400 mgKOH/g or less, still more preferably 300 mgKOH/g or less, and particularly preferably 200 mgKOH/g or less. A weight-average molecular weight (Mw) of the resin having an acid group is preferably 5,000 to 100,000 and more preferably 5,000 to 50,000. In addition, a number-average molecular weight (Mn) of the resin having an acid group is preferably 1,000 to 20,000.

The resin having an acid group preferably includes a repeating unit having an acid group, and more preferably includes 5 to 70 mol% of repeating units having an acid group with respect to the total repeating units of the resin. The upper limit of the content of the repeating unit having an acid group is preferably 50 mol%or less and more preferably 30 mol%or less. The lower limit of the content of the repeating unit having an acid group is preferably 10 mol%or more and more preferably 20 mol%or more.

With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group. In addition, a method of introducing the acid group into the resin is not particularly limited, and examples thereof include the method described in JP6349629B. Further, examples of the method of introducing the acid group into the resin include a method of introducing an acid group by reacting an acid anhydride with a hydroxy group generated by a ring-opening reaction of an epoxy group.

The coloring composition according to the embodiment of the present invention preferably contains a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less.

Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK-Chemie), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF). In addition, as the resin having a basic group, block copolymer (B) described in paragraph Nos. 0063 to 0112 of JP2014-219665A, block copolymer Al described in paragraph Nos. 0046 to 0076 of JP2018-156021A, and a vinyl resin having a basic group, described in paragraph Nos. 0150 to 0153 of JP2019-184763A, can also be used, the contents of which are incorporated herein by reference.

It is also preferable that the coloring composition according to the embodiment of the present invention contains the resin having an acid group and the resin having a basic group, respectively. According to this aspect, the storage stability of the coloring composition can be further improved. In a case where the resin having an acid group and the resin having a basic group are used in combination, a content of the resin having a basic group is preferably 20 to 500 parts by mass, more preferably 30 to 300 parts by mass, and still more preferably 50 to 200 parts by mass with respect to 100 parts by mass of the resin having an acid group.

As the resin, it is also preferable to use a resin including a repeating unit derived from a monomer component including a compound represented by Formula (ED1) and/or a compound represented by Formula (ED2) (hereinafter, these compounds may be referred to as an “ether dimer”).

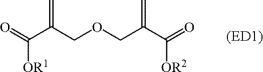

In Formula (ED1), R¹ and R² each independently represent a hydrogen atom or a hydrocarbon group having 1 to 25 carbon atoms, which may have a substituent.

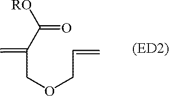

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

As the resin, it is also preferable to use a resin including a repeating unit derived from a compound represented by Formula (X).

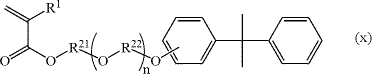

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 to 5, more preferably an integer of 0 to 4, and still more preferably an integer of 0 to 3.

Examples of the compound represented by Formula (X) include ethylene oxide- or propylene oxide- modified (meth)acrylate of para-cumylphenol. Examples of a commercially available product thereof include ARONIX M-110 (manufactured by TOAGOSEI CO., LTD.).

As the resin, it is also preferable to use a resin having a crosslinkable group. Examples of the crosslinkable group include an ethylenically unsaturated bond-containing group and a cyclic ether group.

Examples of the ethylenically unsaturated bond-containing group include a vinyl group, a styrene group, a (meth)allyl group, and a (meth)acryloyl group. Examples of the cyclic ether group include an epoxy group and an oxetanyl group, and an epoxy group is preferable. The epoxy group may be an alicyclic epoxy group. The alicyclic epoxy group means a monovalent functional group having a cyclic structure, in which an epoxy ring and a saturated hydrocarbon ring are fused. The cyclic ether group is preferably at least one selected from a group represented by Formula (e-1) or a group represented by Formula (e-2), and more preferably a group represented by Formula (e-2). In a case where n in Formula (e-1) is 0, the group represented by Formula (e-1) is an epoxy group, and in a case where n is 1, the group represented by Formula (e-1) is an oxetanyl group. In addition, the group represented by Formula (e-2) is an alicyclic epoxy group.

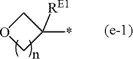

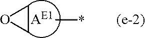

In Formula (e-1), R^{E1}represents a hydrogen atom or an alkyl group, n represents 0 or 1, and * represents a bonding site; and in Formula (e-2), a ring A^{E1} represents an aliphatic hydrocarbon ring and * represents a bonding site.

The alkyl group represented by R^{E1} preferably has 1 to 20 carbon atoms, more preferably has 1 to 10 carbon atoms, still more preferably has 1 to 5 carbon atoms, and particularly preferably has 1 to 3 carbon atoms. The alkyl group represented by R^{E1} is preferably linear or branched, and more preferably linear.

In a case where n is 0, it is preferable that R^{E1} is a hydrogen atom. In a case where n is 1, it is preferable that R^{E1} is a hydrogen atom or an alkyl group having 1 to 3 carbon atoms.

Here, in a case where n in Formula (e-1) is 0, Formula (e-1) is represented by Formula (e-1a).

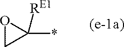

The aliphatic hydrocarbon ring represented by the ring A^{E1} in Formula (e-2) may be a single ring of an aliphatic hydrocarbon ring or a fused ring of an aliphatic hydrocarbon ring. In addition, the aliphatic hydrocarbon ring represented by the ring A^{E1} may have a crosslinking structure. Among these, from the reason that it is easy to form a film having excellent light resistance, a fused ring of an aliphatic hydrocarbon ring is preferable, and a fused ring of an aliphatic hydrocarbon ring, which has a crosslinking structure, is more preferable. Specific examples of the aliphatic hydrocarbon ring represented by the ring A^{E1} include groups represented by Formulae (e-2-1) to (e-2-4), and a group represented by Formula (e-2-3) or a group represented by Formula (e-2-4) is preferable. The groups represented by Formulae (e-2-1) to (e-2-4) may further have a substituent. In the formulae, * represents a bonding site.

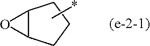

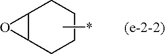

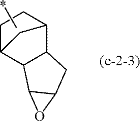

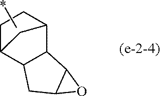

As a resin having a cyclic ether group, it is preferable to use a resin including a repeating unit having a cyclic ether group. Examples of the repeating unit having a cyclic ether group include a repeating unit represented by Formula (A1).

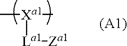

In Formula (A1), X^{a1} represents a trivalent linking group, L^{a1} represents a single bond or a divalent linking group, and Z^{a1} represents a cyclic ether group.

Examples of the trivalent linking group represented by X^{a1} in Formula (A1) include a poly(meth)acrylic linking group, a polyalkyleneimine-based linking group, a polyester-based linking group, a polyurethane-based linking group, a polyurea-based linking group, a polyamide-based linking group, a polyether-based linking group, a polystyrene-based linking group, a bisphenol-based linking group, and a novolac-based linking group; and a poly(meth)acrylic linking group, a polyether-based linking group, a polyester-based linking group, a bisphenol-based linking group, or a novolac-based linking group is preferable, a polyether-based linking group, a novolac-based linking group, or a poly(meth)acrylic linking group is more preferable, and a poly(meth)acrylic linking group is still more preferable.

Examples of the divalent linking group represented by L^{a1} in Formula (A1) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more these groups. The alkylene group may be linear, branched, or cyclic, and is preferably linear or branched. In addition, the alkylene group may have a substituent or may be unsubstituted. Examples of the substituent include a hydroxy group and an alkoxy group.

Examples of the cyclic ether group represented by Z^{a1} in Formula (A1) include an epoxy group and an oxetanyl group, and an epoxy group is preferable. In addition, the cyclic ether group represented by Z^{a1} is preferably the group represented by Formula (e-1) or the group represented by Formula (e-2), and more preferably the group represented by Formula (e-2).

The resin having a cyclic ether group is preferably a resin having at least one repeating unit selected from a repeating unit represented by Formula (1) or a repeating unit represented by Formula (2). The above-described resin may include only one of the repeating unit represented by Formula (1) or the repeating unit represented by Formula (2), or may include both of the repeating unit represented by Formula (1) and the repeating unit represented by Formula (2).

In a case of including both of the repeating units, a molar ratio of the repeating unit represented by Formula (1) and the repeating unit represented by Formula (2) is repeating unit represented by Formula (1):repeating unit represented by Formula (2) = preferably 5:95 to 95:5, more preferably 10:90 to 90:10, and still more preferably 20:80 to 80:20.

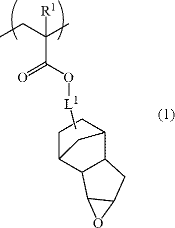

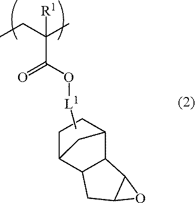

In Formulae (1) and (2), L¹ represents a single bond or a divalent linking group, and R¹ represents a hydrogen atom or a substituent. Examples of the substituent represented by R¹ include an alkyl group and an aryl group, and an alkyl group is preferable. The alkyl group preferably has 1 to 10 carbon atoms, more preferably has 1 to 5 carbon atoms, and still more preferably has 1 to 3 carbon atoms. R¹ is preferably a hydrogen atom or a methyl group. Examples of the divalent linking group represented by L¹ include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more these groups. The alkylene group may be linear, branched, or cyclic, and is preferably linear or branched. In addition, the alkylene group may have a substituent or may be unsubstituted. Examples of the substituent include a hydroxy group and an alkoxy group.

A content of the repeating unit having a cyclic ether group in the resin having a cyclic ether group is preferably 1 to 100 mol% in the total repeating units of the resin having a cyclic ether group. The upper limit is preferably 90 mol% or less and more preferably 80 mol% or less. The lower limit is preferably 2 mol% or more and more preferably 3 mol% or more.

The resin having a cyclic ether group may have a repeating unit other than the repeating unit having a cyclic ether group. Examples of other repeating units include a repeating unit having an acid group (hereinafter, also referred to as a repeating unit B-1), a repeating unit having a group in which an acid group is protected by a protective group (hereinafter, also referred to as a repeating unit B-2), and a repeating unit having an ethylenically unsaturated bond-containing group (hereinafter, also referred to as a repeating unit B-3).

Examples of the acid group in the above-described repeating unit B-1 and the acid group protected by the above-described protective group in the above-described repeating unit B-2 include a phenolic hydroxy group, a carboxy group, a sulfo group, and a phosphoric acid group, and a phenolic hydroxy group or a carboxy group is preferable and a carboxy group is more preferable.

Examples of the protective group which protects the above-described acid group in the above-described repeating unit B-2 include a group which is decomposed and eliminated by action of acid or base. The protective group is preferably a group represented by any one of Formulae (Y1) to (Y5), and from the reason that it is easy to deprotect, a group represented by Formula (Y3) or Formula (Y5) is more preferable.

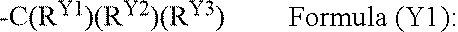

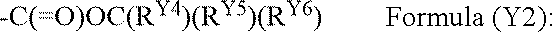

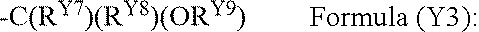

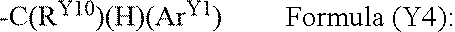

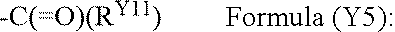

In Formula (Y1), R^{Y1} to R^{Y3} each independently represent an alkyl group, and two of R^{Y1} to R^{Y3} may be bonded to each other to form a ring;
in Formula (Y2), R^{Y4} to R^{Y6} each independently represent an alkyl group, and two of R^{Y4} to R^{Y6} may be bonded to each other to form a ring;
in Formula (Y3), R^{Y7} and R^{Y8} each independently represent a hydrogen atom, an alkyl group, or an aryl group, in which at least one of R^{Y7} or R^{Y8} is an alkyl group or an aryl group, R^{Y9} represents an alkyl group or an aryl group, and R^{Y7} or R^{Y8}, and R^{Y9} may be bonded to each other to form a ring;
in Formula (Y4), Ar^{Y1} represents an aryl group, and R^{Y10} represents an alkyl group or an aryl group; and
in Formula (Y5), R^{Y11} represents an alkyl group or an aryl group.

The alkyl group represented by R^{Y1} to R^{Y3} in Formula (Y1) preferably has 1 to 12 carbon atoms, more preferably has 1 to 6 carbon atoms, and still more preferably has 1 to 4 carbon atoms. The alkyl group may be linear, branched, or cyclic, and is preferably linear or branched. In Formula (Y1), two of R^{Y1} to R^{Y3} may be bonded to each other to form a ring. Examples of the ring formed by bonding two of R^{Y1} to R^{Y3} to each other include a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group, and a monocyclic cycloalkyl group having 5 or 6 carbon atoms is preferable. In addition, in the above-described cycloalkyl group, one of methylene groups constituting the ring may be replaced with a heteroatom such as an oxygen atom or a group having a heteroatom, such as a carbonyl group.

The alkyl group represented by R^{Y4} to R^{Y6} in Formula (Y2) preferably has 1 to 12 carbon atoms, more preferably has 1 to 6 carbon atoms, and still more preferably has 1 to 4 carbon atoms. The alkyl group may be linear, branched, or cyclic, and is preferably linear or branched. It is preferable that at least two of R^{Y4}, ..., or R^{Y6} in Formula (Y2) are methyl groups. In Formula (Y2), two of R^{Y4} to R^{Y6} may be bonded to each other to form a ring. Examples of the ring to be formed include the rings described in Formula (Y1).

In Formula (Y3), R^{Y7} and R^{Y8} each independently represent a hydrogen atom, an alkyl group, or an aryl group, in which at least one of R^{Y7} or R^{Y8} is an alkyl group or an aryl group, R^{Y9} represents an alkyl group or an aryl group, and R^{Y7} or R^{Y8}, and R^{Y9} may be bonded to each other to form a ring.

The alkyl group may be linear, branched, or cyclic. The alkyl group preferably has 1 to 12 carbon atoms, more preferably has 1 to 6 carbon atoms, and still more preferably 1 to 4 carbon atoms. The aryl group preferably has 6 to 20 carbon atoms, and more preferably 6 to 12 carbon atoms. Examples of the ring formed by bonding R^{Y7} or R^{Y8}, and R^{Y9} to each other include a tetrahydrofuranyl group and a tetrahydropyranyl group. In Formula (Y3), it is preferable that R^{Y7} or R^{Y8}, and R^{Y9} are bonded to each other to form a ring. In addition, it is preferable that one of R^{Y7} or R^{Y8} is a hydrogen atom.

In Formula (Y4), Ar^{Y1} represents an aryl group, R^{Y10} represents an alkyl group or an aryl group, and Ar^{Y1} and R^{Y10} may be bonded to each other to form a ring. The alkyl group preferably has 1 to 12 carbon atoms, more preferably has 1 to 6 carbon atoms, and still more preferably 1 to 4 carbon atoms. The aryl group preferably has 6 to 20 carbon atoms, and more preferably 6 to 12 carbon atoms. It is preferable that R^{Y10} in Formula (Y4) is an alkyl group.

In Formula (Y5), R^{Y11} represents an alkyl group or an aryl group, and is preferably an alkyl group. The alkyl group preferably has 1 to 12 carbon atoms, more preferably has 1 to 6 carbon atoms, and still more preferably 1 to 4 carbon atoms. The aryl group preferably has 6 to 20 carbon atoms, and more preferably 6 to 12 carbon atoms.

A molecular weight of the protective group is preferably 40 to 200, more preferably 40 to 150, and still more preferably 40 to 120. In a case where the molecular weight of the protective group is within the above-described range, a coloring composition having excellent storage stability and excellent curing properties at a low temperature can be obtained.

Specific examples of the protective group include a 1-methoxyethyl group, a 1-ethoxyethyl group, a 1-n-propoxyethyl group, a 1-n-butoxyethyl group, a 1-t-butoxyethyl group, a 1-cyclopentyloxyethyl group, a 1-cyclohexyloxyethyl group, a cyclohexyl(methoxy)methyl group, an α-methoxybenzyl group, an α-ethoxybenzyl group, an α-n-propoxybenzyl group, a 2-phenyl-1-methoxyethyl group, a 2-phenyl-1-ethoxyethyl group, a 2-phenyl-1-i-propoxyethyl group, a 2-tetrahydrofuranyl group, and a 2-tetrahydropyranyl group; and a 1-ethoxyethyl group, a 1-cyclohexyloxyethyl group, a 2-tetrahydrofuranyl group, or a 2-tetrahydropyranyl group is preferable, and a 1-ethoxyethyl group or a 1-cyclohexyloxyethyl group is more preferable.

Examples of the ethylenically unsaturated bond-containing group included in the repeating unit B-3 include a vinyl group, a styrene group, a (meth)allyl group, and a (meth)acryloyl group.

Examples of the repeating unit B-1 include a repeating unit represented by Formula (B1). In addition, examples of the repeating unit B-2 include a repeating unit represented by Formula (B2). In addition, examples of the repeating unit B-3 include a repeating unit represented by Formula (B3).

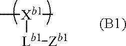

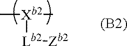

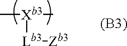

In Formula (B1), X^{b1} represents a trivalent linking group, L^{b1} represents a single bond or a divalent linking group, and Z^{b1} represents an acid group.

In Formula (B2), X^{b2} represents a trivalent linking group, L^{b2} represents a single bond or a divalent linking group, and Z^{b2} represents a group in which an acid group is protected by a protective group.

In Formula (B3), X^{b3} represents a trivalent linking group, L^{b3} represents a single bond or a divalent linking group, and Z^{b3} represents an ethylenically unsaturated bond-containing group.

The trivalent linking group represented by X^{b1} in Formula (B1), the trivalent linking group represented by X^{b2} in Formula (B2), and the trivalent linking group represented by X^{b3} in Formula (B3) are not particularly limited. Examples thereof include a poly(meth)acrylic linking group, a polyalkyleneimine-based linking group, a polyester-based linking group, a polyurethane-based linking group, a polyurea-based linking group, a polyamide-based linking group, a polyether-based linking group, a polystyrene-based linking group, a bisphenol-based linking group, and a novolac-based linking group; and a poly(meth)acrylic linking group, a polyether-based linking group, a polyester-based linking group, a bisphenol-based linking group, or a novolac-based linking group is preferable, and a poly(meth)acrylic linking group is more preferable.

Examples of the divalent linking group represented by L^{b1} in Formula (B1), the divalent linking group represented by L^{b2} in Formula (B2), and the divalent linking group represented by L^{b3} in Formula (B3) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more these groups. The alkylene group may be linear, branched, or cyclic, and is preferably linear or branched. In addition, the alkylene group may have a substituent or may be unsubstituted. Examples of the substituent include a hydroxy group and an alkoxy group.

Examples of the acid group represented by Z^{b1} in Formula (B1) include a phenolic hydroxy group, a carboxy group, a sulfo group, and a phosphoric acid group, and a phenolic hydroxy group or a carboxy group is preferable and a carboxy group is more preferable.

Examples of the group in which an acid group is protected by a protective group, represented by Z^{b2} in Formula (B2), include a group in which an acid group is protected by the group represented by any one of Formulae (Y1) to (Y5) described above, and a group in which an acid group is protected by the group represented by Formula (Y3) or Formula (Y5) is preferable. Examples of the above-described acid group include a phenolic hydroxy group, a carboxy group, a sulfo group, and a phosphoric acid group, and a phenolic hydroxy group or a carboxy group is preferable and a carboxy group is more preferable.

Examples of the ethylenically unsaturated bond-containing group represented by Z^{b3} in Formula (B3) include a vinyl group, a styrene group, a (meth)allyl group, and a (meth)acryloyl group.

In a case where the resin having a cyclic ether group includes the repeating unit B-1, a content of the unit B-1 in the resin having a cyclic ether group is preferably 5 to 85 mol% in the total repeating units of the resin having a cyclic ether group. The upper limit is preferably 60 mol% or less and more preferably 40 mol% or less. The lower limit is preferably 8 mol% or more and more preferably 10 mol% or more.

In a case where the resin having a cyclic ether group includes the repeating unit B-2, a content of the unit B-2 in the resin having a cyclic ether group is preferably 1 to 65 mol% in the total repeating units of the resin having a cyclic ether group. The upper limit is preferably 45 mol% or less and more preferably 30 mol% or less. The lower limit is preferably 2 mol% or more and more preferably 3 mol% or more.

In a case where the resin having a cyclic ether group includes each of the repeating unit B-1 and the repeating unit B-2, the resin having a cyclic ether group preferably includes 0.4 to 3.2 mol of the repeating unit B-2 with respect to 1 mol of the repeating unit B-1, more preferably includes 0.8 to 2.8 mol thereof, and still more preferably includes 1.2 to 2.4 mol thereof.

In a case where the resin having a cyclic ether group includes the repeating unit B-3, a content of the unit B-3 in the resin having a cyclic ether group is preferably 1 to 65 mol% in the total repeating units of the resin having a cyclic ether group. The upper limit is preferably 45 mol% or less and more preferably 30 mol% or less. The lower limit is preferably 2 mol% or more and more preferably 3 mol% or more.

The resin having a cyclic ether group preferably further includes a repeating unit having an aromatic hydrocarbon ring. The aromatic hydrocarbon ring is preferably a benzene ring or a naphthalene ring, and more preferably a benzene ring. The aromatic hydrocarbon ring may have a substituent. Examples of the substituent include an alkyl group. In a case where the resin having a cyclic ether group includes the repeating unit having an aromatic hydrocarbon ring, a content of the repeating unit having an aromatic hydrocarbon ring is preferably 1 to 65 mol% in the total repeating units of the resin having a cyclic ether group. The upper limit is preferably 45 mol% or less and more preferably 30 mol% or less. The lower limit is preferably 2 mol% or more and more preferably 3 mol% or more. Examples of the repeating unit having an aromatic hydrocarbon ring include a repeating unit derived from a monofunctional polymerizable compound having an aromatic hydrocarbon ring, such as vinyltoluene and benzyl (meth)acrylate.

Examples of a commercially available product of the resin having a cyclic ether group include EPICLON HP5000 and EPICLON HP4032D (both of which are manufactured by DIC Corporation) as a naphthalene-modified epoxy resin. Examples thereof include EPICLON 820 (manufactured by DIC Corporation) as an alkyldiphenol-type epoxy resin. Examples thereof include jER825, jER827, jER828, jER834, jER1001, jER1002, jER1003, jER1055, jER1007, jER1009, and jER1010 (all of which are manufactured by Mitsubishi Chemical Corporation); and EPICLON 860, EPICLON 1050, EPICLON 1051, and EPICLON 1055 (all of which are manufactured by DIC Corporation) as a bisphenol A-type epoxy resin. Examples thereof include jER806, jER807, jER4004, jER4005, jER4007, and jER4010 (all of which are manufactured by Mitsubishi Chemical Corporation); EPICLON 830 and EPICLON 835 (both of which are manufactured by DIC Corporation); and LCE-21 and RE-602S (both of which are manufactured by Nippon Kayaku Co., Ltd.) as a bisphenol F-type epoxy resin. Examples thereof include jER152, jER154, jER157S70, and jER157S65 (all of which are manufactured by Mitsubishi Chemical Corporation); and EPICLON N-740, EPICLON N-770, and EPICLON N-775 (all of which are manufactured by DIC Corporation) as a phenol novolac-type epoxy resin. Examples thereof include EPICLON N-660, EPICLON N-665, EPICLON N-670, EPICLON N-673, EPICLON N-680, EPICLON N-690, and EPICLON N-695 (all of which are manufactured by DIC Corporation); and EOCN-1020 (manufactured by Nippon Kayaku Co., Ltd.) as a cresol novolac-type epoxy resin. Examples thereof include ADEKA RESIN EP-4080S, EP-4085S, and EP-4088S (all of which are manufactured by ADEKA Corporation); CELLOXIDE 2021P, CELLOXIDE 2081, CELLOXIDE 2083, CELLOXIDE 2085, EHPE 3150, EPOLEAD PB 3600, and EPOLEAD PB 4700 (all of which are manufactured by DAICEL-ALLNEX LTD.); and DENACOL EX-212L, EX-214L, EX-216L, EX-321L, and EX-850L (all of which are manufactured by Nagase ChemteX Corporation) as an aliphatic epoxy resin. In addition, as the resin having a cyclic ether group, resins described in paragraph Nos. 0034 to 0036 of JP2013-011869A, resins described in paragraph Nos. 0147 to 0156 of JP2014-043556A, resins described in paragraph Nos. 0085 to 0092 of JP2014-089408A, resins described in JP2017-179172A, resins described in paragraph Nos. 0027 to 0055 and 0096 of JP2018-180081A, resins described in paragraph Nos. 0117 to 0120 of JP2020-515680A, and resins described in paragraph No. 0084 of WO2020/175011A can also be used.

As the resin, it is also preferable to use a resin (hereinafter, also referred to as a resin Ac) having an aromatic carboxy group. The resin Ac may include the aromatic carboxy group in the main chain of the repeating unit, or in the side chain of the repeating unit. It is preferable that the aromatic carboxy group is included in the main chain of the repeating unit. In the present specification, the aromatic carboxy group is a group having a structure in which one or more carboxy groups are bonded to an aromatic ring. In the aromatic carboxy group, the number of carboxy groups bonded to an aromatic ring is preferably 1 to 4 and more preferably 1 or 2.

The resin Ac is preferably a resin including at least one repeating unit selected from a repeating unit represented by Formula (Ac-1) or a repeating unit represented by Formula (Ac-2).

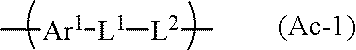

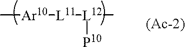

In Formula (Ac-1), Ar¹ represents a group including an aromatic carboxy group, L¹ represents —COO— or —CONH—, and L² represents a divalent linking group.

In Formula (Ac-2), Ar¹⁰ represents a group including an aromatic carboxy group, L¹¹ represents —COO— or —CONH—, L¹² represents a trivalent linking group, and P¹⁰ represents a polymer chain.

In Formula (Ac-1), examples of the group including an aromatic carboxy group, represented by Ar¹, include a structure derived from an aromatic tricarboxylic anhydride and a structure derived from an aromatic tetracarboxylic anhydride. Examples of the aromatic tricarboxylic anhydride and the aromatic tetracarboxylic anhydride include compounds having the following structures.

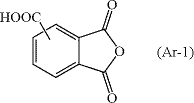

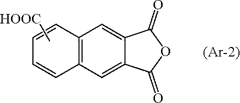

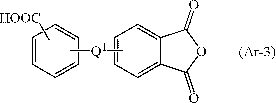

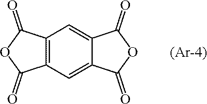

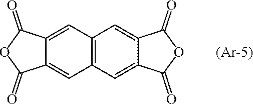

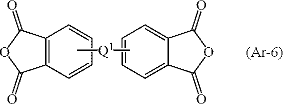

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

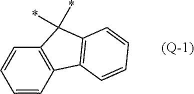 [SMILES: *C1(*)c2ccccc2-c2ccccc21]

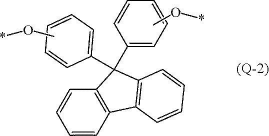

The group including an aromatic carboxy group, which is represented by Ar¹, may have a crosslinkable group. As the crosslinkable group, an ethylenically unsaturated bond-containing group or a cyclic ether group is preferable, and an ethylenically unsaturated bond-containing group is more preferable. Specific examples of the group including an aromatic carboxy group represented by Ar¹ include a group represented by Formula (Ar-11), a group represented by Formula (Ar-12), and a group represented by Formula (Ar-13).

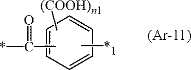

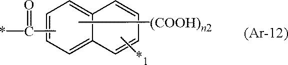

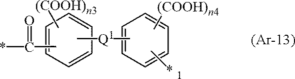

In Formula (Ar-11), n1 represents an integer of 1 to 4, and is preferably 1 or 2 and more preferably 2.

In Formula (Ar-12), n2 represents an integer of 1 to 8, and is preferably an integer of 1 to 4, more preferably 1 or 2, and still more preferably 2.

In Formula (Ar-13), n3 and n4 each independently represent an integer of 0 to 4, and are preferably an integer of 0 to 2, more preferably 1 or 2, and still more preferably 1. However, at least one of n3 or n4 is an integer of 1 or more.

In Formula (Ar-13), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formulae (Ar-11) to (Ar-13), ^{∗}1 represents a bonding position with L¹.

In Formula (Ac-1), L¹ represents —COO— or —CONH—, preferably —COO—.

In Formula (Ac-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by —L^{2a}—O—. Examples of L^{2a} include an alkylene group; an arylene group; a group formed by a combination of an alkylene group and an arylene group; and a group formed by a combination of at least one selected from an alkylene group or an arylene group; and at least one selected from —O—, —CO—, —COO—, —OCO—, —NH—, or —S—, and an alkylene group is preferable. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxy group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L12-2).

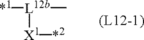

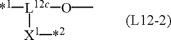

In Formula (L12-1), L^{12b} represents a trivalent linking group, X¹ represents S, ^{∗}1 represents a bonding position with L¹¹ in Formula (Ac-2), and *2 represents a bonding position with P¹⁰ in Formula (Ac-2). Examples of the trivalent linking group represented by L^{12b} include a hydrocarbon group; and a group formed by a combination of a hydrocarbon group and at least one selected from —O—, —CO—, —COO—, —OCO—, —NH—, or —S—, and a hydrocarbon group or a group in which a hydrocarbon group and —O— are combined is preferable.

In Formula (L12-2), L^{12c} represents a trivalent linking group, X¹ represents S, ^{∗}1 represents a bonding position with L¹¹ in Formula (Ac-2), and *2 represents a bonding position with P¹⁰ in Formula (Ac-2). Examples of the trivalent linking group represented by L^{12c} include a hydrocarbon group; and a group formed by a combination of a hydrocarbon group and at least one selected from —O—, —CO—, —COO—, —OCO—, —NH—, or —S—, and a hydrocarbon group is preferable.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. A weight-average molecular weight of the polymer chain P¹⁰ is preferably 500 to 20,000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxy group is a resin having the repeating unit represented by Formula (Ac-2), this resin is preferably used as a dispersant.

The polymer chain represented by P¹⁰ may include a crosslinkable group. Examples of the crosslinkable group include an ethylenically unsaturated bond-containing group and a cyclic ether group.

It is preferable that the coloring composition according to the embodiment of the present invention contains a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol% or more in a case where the total amount of the acid group and the basic group is 100 mol%. The acid group included in the acidic dispersant (acidic resin) is preferably a carboxy group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol% in a case where the total amount of the acid group and the basic group is 100 mol%. The basic group included in the basic dispersant is preferably an amino group.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. The content of the repeating unit having an ethylenically unsaturated bond-containing group in the side chain is preferably 10 mol% or more, more preferably 10 to 80 mol%, and still more preferably 20 to 70 mol% with respect to the total repeating units of the resin.

In addition, as the dispersant, a resin described in JP2018-087939A, block copolymers (EB-1) to (EB-9) described in paragraph Nos. 0219 to 0221 of JP6432077B, polyethyleneimine having a polyester side chain, described in WO2016/104803A, a block copolymer described in WO2019/125940A, a block polymer having an acrylamide structural unit, described in JP2020-066687A, a block polymer having an acrylamide structural unit, described in JP2020-066688A, a dispersant described in WO2016/104803A, or the like can also be used.

A commercially available product is also available as the dispersant, and specific examples thereof include DISPERBYK series (for example, DISPERBYK-111, 161, 2001, and the like) manufactured by BYK-Chemie, Solsperse series (for example, Solsperse 20000, 76500, and the like) manufactured by Lubrizol Japan Ltd., and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

A content of the resin in the total solid content of the coloring composition is preferably 10% to 60% by mass. The upper limit is preferably 55% by mass or less and more preferably 50% by mass or less. The lower limit is preferably 15% by mass or more and more preferably 20% by mass or more.

In addition, with respect to 100 parts by mass of the colorant, the coloring composition according to the embodiment of the present invention preferably contains 100 to 350 parts by mass of the resin, more preferably contains 120 to 300 parts by mass of the resin, and still more preferably contains 140 to 250 parts by mass of the resin.

In addition, in the resin, a content of the resin having at least one repeating unit selected from the repeating unit represented by Formula (1) described above or the repeating unit represented by Formula (2) is preferably 10% by mass or more, more preferably 20% by mass or more, and still more preferably 30% by mass or more. The upper limit may be 100% by mass or less, 90% by mass or less, or 80% by mass or less.

The coloring composition according to the embodiment of the present invention may contain one resin or two or more kinds of resins. In a case of containing two or more kinds of resins, it is preferable that the total amount thereof is within the above-described range.

### <<Polymerizable Compound>>

The coloring composition according to the embodiment of the present invention contains a polymerizable compound. Examples of the polymerizable compound include a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3,000. The upper limit is preferably 2,000 or less and more preferably 1,500 or less. The lower limit is preferably 150 or more and more preferably 250 or more.

From the viewpoint of temporal stability of the coloring composition, an ethylenically unsaturated bond-containing group value (hereinafter, referred to as a C=C value) of the polymerizable compound is preferably 2 to 14 mmol/g. The lower limit is preferably 3 mmol/g or more, more preferably 4 mmol/g or more, and still more preferably 5 mmol/g or more. The upper limit is preferably 12 mmol/g or less, more preferably 10 mmol/g or less, and still more preferably 8 mmol/g or less. The C=C value of the polymerizable compound is obtained by dividing the number of ethylenically unsaturated bond-containing groups included in one molecule of the polymerizable compound by the molecular weight of the polymerizable compound.

The polymerizable compound is preferably a compound including three or more ethylenically unsaturated bond-containing groups, and more preferably a compound including four or more ethylenically unsaturated bond-containing groups. From the viewpoint of temporal stability of the coloring composition, the upper limit of the number of ethylenically unsaturated bond-containing groups is preferably 15 or less, more preferably 10 or less, and still more preferably 6 or less. In addition, as the polymerizable compound, a (meth)acrylate compound having 3 or more functional groups is preferable, a (meth)acrylate compound having 3 to 15 functional groups is more preferable, a (meth)acrylate compound having 3 to 10 functional groups is still more preferable, and a (meth)acrylate compound having 3 to 6 functional groups is particularly preferable.

Examples of the polymerizable compound include dipentaerythritol tri(meth)acrylate, dipentaerythritol tetra(meth)acrylate, dipentaerythritol penta(meth)acrylate, dipentaerythritol hexa(meth)acrylate, and a modified product of these compounds. Examples of the modified product include a compound having a structure in which a (meth)acryloyl group of the above-described compound is bonded through an alkyleneoxy group, such as ethoxylated dipentaerythritol hexa(meth)acrylate. Specific examples thereof include a compound represented by Formula (Z-4) and a compound represented by Formula (Z-5).

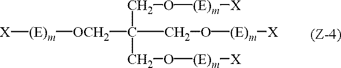

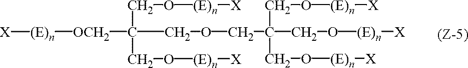

In Formulae (Z-4) and (Z-5), E’s each independently represent —((CH₂)_{y}CH₂O)— or —((CH₂)_{y}CH(CH₃)O)—, y’s each independently represent an integer of 0 to 10, and X’s each independently represent a (meth)acryloyl group, a hydrogen atom, or a carboxy group. In Formula (Z-4), the total number of (meth)acryloyl groups is 3 or 4, m’s each independently represent an integer of 0 to 10, and the sum of m’s is an integer of 0 to 40. In Formula (Z-5), the total number of (meth)acryloyl groups is 5 or 6, n’s each independently represent an integer of 0 to 10, and the sum of n’s is an integer of 0 to 60.

In Formula (Z-4), m is preferably an integer of 0 to 6 and more preferably an integer of 0 to 4. In addition, the total number of m’s is preferably an integer of 2 to 40, more preferably an integer of 2 to 16, and still more preferably an integer of 4 to 8.

In Formula (Z-5), n is preferably an integer of 0 to 6 and more preferably an integer of 0 to 4. In addition, the sum of n’s is preferably an integer of 3 to 60, more preferably an integer of 3 to 24, and still more preferably an integer of 6 to 12.

In addition, an aspect in which a terminal on the oxygen atom side of E, that is, —((CH₂)_{y}CH₂O)— or —((CH₂)_{y}CH(CH₃)O)— in Formula (Z-4) or Formula (Z-5) is bonded to X is preferable.

In addition, as the polymerizable compound, polypentaerythritol poly(meth)acrylate as represented by Formula (Z-6) can also be used.

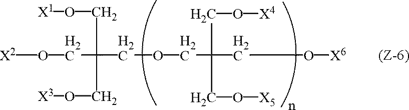

In Formula (Z-6), X¹ to X⁶ each independently represent a hydrogen atom or a (meth)acryloyl group, and n represents an integer of 1 to 10. However, at least one of X¹, ..., or X⁶ is a (meth)acryloyl group.

The polymerizable compound used in the present invention is preferably at least one selected from the group consisting of dipentaerythritol hexa(meth)acrylate, dipentaerythritol penta(meth)acrylate, polypentaerythritol poly(meth)acrylate, and a modified product of these compounds. Examples of a commercially available product thereof include KAYARAD D-310, DPHA, and DPEA-12 (all of which are manufactured by Nippon Kayaku Co., Ltd.), and NK ESTER A-DPH-12E and TPOA-50 (manufactured by Shin-Nakamura Chemical Co., Ltd.).

In addition, as the polymerizable compound, diglycerin ethylene oxide (EO)-modified (meth)acrylate (as a commercially available product, M-460 manufactured by TOAGOSEI CO., LTD.), pentaerythritol tetra(meth)acrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), EBECRYL80 (manufactured by DAICEL-ALLNEX LTD., amine-containing tetrafunctional acrylate), and the like can also be used.

In addition, as the polymerizable compound it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable compound, a compound having an acid group such as a carboxy group, a sulfo group, and a phosphoric acid group can also be used. Examples of a commercially available product of such a compound include ARONIX M-305, M-510, M-520, and ARONIX TO-2349 (manufactured by TOAGOSEI CO., LTD.).

In addition, as the polymerizable compound, a compound having a caprolactone structure can also be used. With regard to the compound having a caprolactone structure, reference can be made to the description in paragraph Nos. 0042 to 0045 of JP2013-253224A, the content of which is incorporated herein by reference. Examples of the compound having a caprolactone structure include DPCA-20, DPCA-30, DPCA-60, and DPCA-120, each of which is commercially available as KAYARAD DPCA series from Nippon Kayaku Co., Ltd.

In addition, as the polymerizable compound, a polymerizable compound having a fluorene skeleton can also be used. Examples of a commercially available product thereof include OGSOL EA-0200 and EA-0300 (manufactured by Osaka Gas Chemicals Co., Ltd., (meth)acrylate monomer having a fluorene skeleton).

In addition, as the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

In addition, urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

A content of the polymerizable compound in the total solid content of the coloring composition is preferably 5% to 50% by mass. The upper limit is preferably 40% by mass or less and more preferably 30% by mass or less. The lower limit is preferably 7% by mass or more and more preferably 10% by mass or more.

In addition, it is preferable that the coloring composition contains 20 to 200 parts by mass of the polymerizable compound with respect to 100 parts by mass of the resin. The upper limit is preferably 150 parts by mass or less and more preferably 100 parts by mass or less. The lower limit is preferably 30 parts by mass or more and more preferably 40 parts by mass or more.

The coloring composition according to the embodiment of the present invention may contain one kind of the polymerizable compound or two or more kinds of the polymerizable compounds. In a case of containing two or more kinds of the polymerizable compounds, it is preferable that the total content thereof is within the above-described range.

### <<Photopolymerization Initiator>>

The coloring composition according to the embodiment of the present invention contains a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole compound, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a hexaarylbiimidazole compound, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, peroxide initiators described in JP2019-167313A, aminoacetophenone-based initiators described in JP2020-055992A, oxime-based photopolymerization initiators described in JP2013-190459A, and polymers described in JP2020-172619A, the contents of which are incorporated herein by reference.

Specific examples of the hexaarylbiimidazole compound include 2,2′,4-tris(2-chlorophenyl)-5-(3,4-dimethoxyphenyl)-4,5-diphenyl-1,1′-biimidazole.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, 2-ethoxycarbonyloxyimino-1-phenylpropane-1-one, and 1-[4-(phenylthio)phenyl]-3-cyclohexyl-propane-1,2-dione-2-(O-acetyloxime). Examples of a commercially available product thereof include Irgacure OXE01, Irgacure OXE02, Irgacure OXE03, and Irgacure OXE04 (all of which are manufactured by BASF), TR-PBG-304 and TR-PBG-327 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, compounds described in JP6636081B, and compounds described in KR10-2016-0109444A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

As the photopolymerization initiator, an oxime compound in which a substituent having a hydroxy group is bonded to a carbazole skeleton can also be used. Examples of such a photopolymerization initiator include compounds described in WO2019/088055A.

As the photopolymerization initiator, an oxime compound having an aromatic ring group Ar^{OX1} in which an electron withdrawing group is introduced into an aromatic ring (hereinafter, also referred to as an oxime compound OX) is used can also be used. Examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

The oxime compound OX is preferably at least one selected from a compound represented by Formula (OX1) or a compound represented by Formula (OX2), and more preferably a compound represented by Formula (OX2).

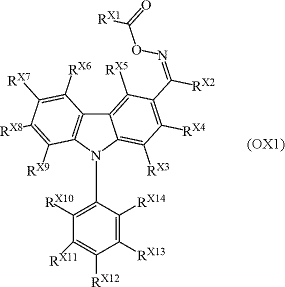

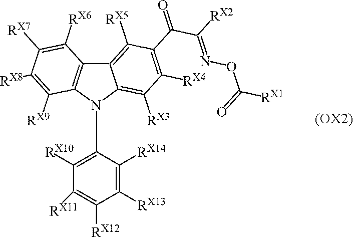

In the formulae, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group.

R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group.

R^{X3} to R^{X14} each independently represent a hydrogen atom or a substituent. However, at least one of R^{X10}, ..., or R^{X14} is an electron withdrawing group.

Examples of the electron withdrawing group include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable.

In the formulae, it is preferable that R^{Xı2} is an electron withdrawing group, and R^{X10}, R^{X11}, R^{X13}, and R^{X14} are hydrogen atoms.

Specific examples of the oxime compound OX include compounds described in paragraph Nos. 0083 to 0105 of JP4600600B.

Specific examples of the oxime compound which are preferably used in the present invention are shown below, but the present invention is not limited thereto. [0149]

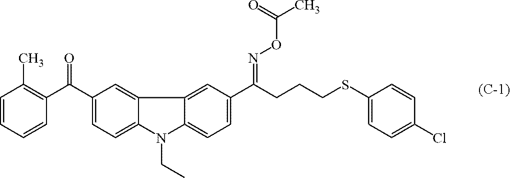 [SMILES: CCn1c2ccc(C(=O)c3ccccc3C)cc2c2cc(/C(CCCSc3ccc(Cl)cc3)=N/OC(C)=O)ccc21]

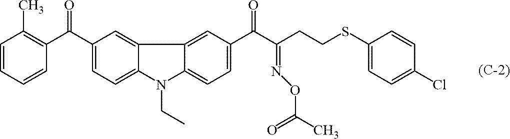 [SMILES: CCn1c2ccc(C(=O)/C(CCSc3ccc(Cl)cc3)=N/OC(C)=O)cc2c2cc(C(=O)c3ccccc3C)ccc21]

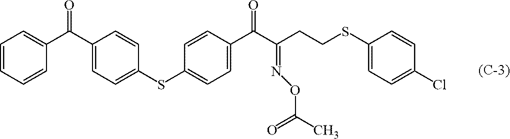 [SMILES: CC(=O)O/N=C(\CCSc1ccc(Cl)cc1)C(=O)c1ccc(Sc2ccc(C(=O)c3ccccc3)cc2)cc1]

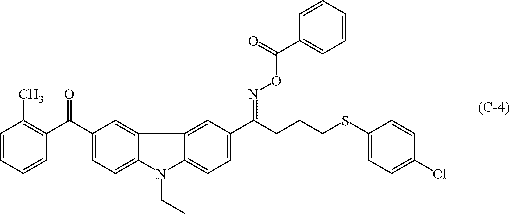 [SMILES: CCn1c2ccc(C(=O)c3ccccc3C)cc2c2cc(/C(CCCSc3ccc(Cl)cc3)=N/OC(=O)c3ccccc3)ccc21]

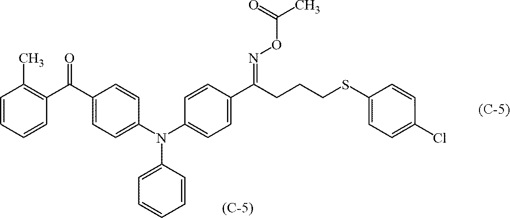 [SMILES: CC(=O)O/N=C(\CCCSc1ccc(Cl)cc1)c1ccc(N(c2ccccc2)c2ccc(C(=O)c3ccccc3C)cc2)cc1 ; "(C-5)"]

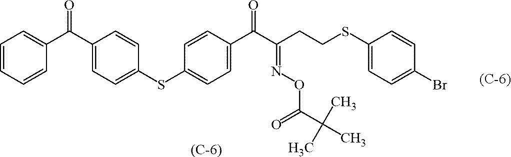 [SMILES: CC(C)(C)C(=O)O/N=C(\CCSc1ccc(Br)cc1)C(=O)c1ccc(Sc2ccc(C(=O)c3ccccc3)cc2)cc1 ; "(C-6)"]

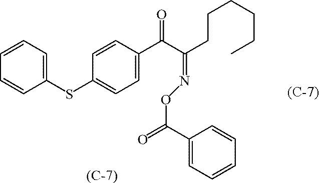 [SMILES: CCCCCC/C(=N/OC(=O)c1ccccc1)C(=O)c1ccc(Sc2ccccc2)cc1 ; "(C-7)"]

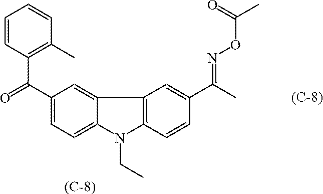 [SMILES: CCn1c2ccc(C(=O)c3ccccc3C)cc2c2cc(/C(C)=N/OC(C)=O)ccc21 ; "(C-8)"]

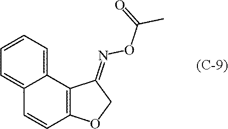 [SMILES: CC(=O)O/N=C1\COc2ccc3ccccc3c21]

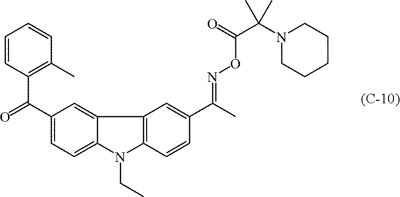 [SMILES: CCn1c2ccc(C(=O)c3ccccc3C)cc2c2cc(/C(C)=N/OC(=O)C(C)(C)N3CCCCC3)ccc21]

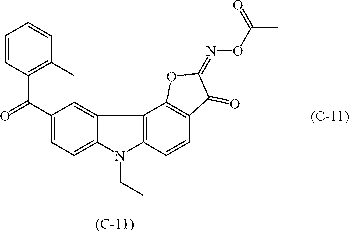 [SMILES: CCn1c2ccc(C(=O)c3ccccc3C)cc2c2c3c(ccc21)C(=O)/C(=N\OC(C)=O)O3 ; "(C-11)"]

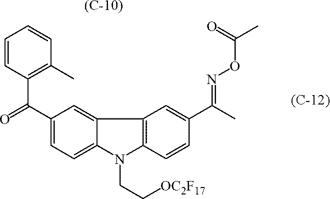

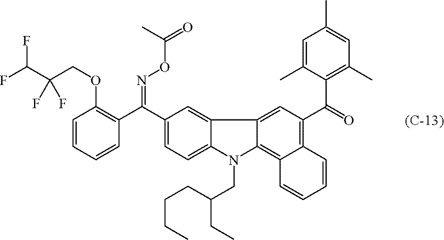 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

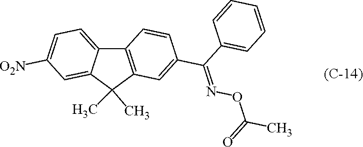 [SMILES: CC(=O)O/N=C(\c1ccccc1)c1ccc2c(c1)C(C)(C)c1cc([N+](=O)[O-])ccc1-2]

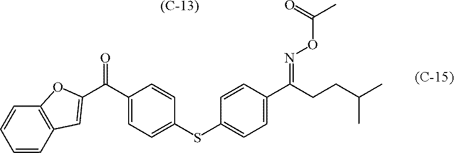 [SMILES: CC(=O)O/N=C(\CCC(C)C)c1ccc(Sc2ccc(C(=O)c3cc4ccccc4o3)cc2)cc1 ; "(C-13)"]

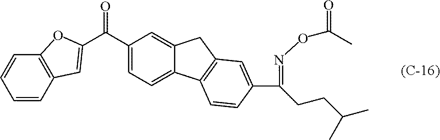 [SMILES: CC(=O)O/N=C(\CCC(C)C)c1ccc2c(c1)Cc1cc(C(=O)c3cc4ccccc4o3)ccc1-2]

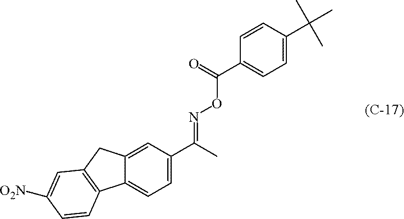 [SMILES: C/C(=N\OC(=O)c1ccc(C(C)(C)C)cc1)c1ccc2c(c1)Cc1cc([N+](=O)[O-])ccc1-2]

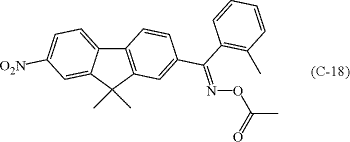 [SMILES: CC(=O)O/N=C(/c1ccc2c(c1)C(C)(C)c1cc([N+](=O)[O-])ccc1-2)c1ccccc1C]

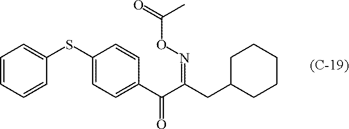 [SMILES: CC(=O)O/N=C(/CC1CCCCC1)C(=O)c1ccc(Sc2ccccc2)cc1]

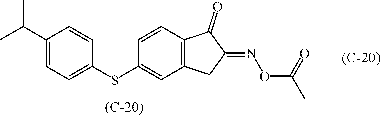

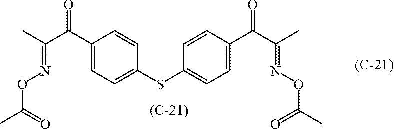

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian) using an ethyl acetate solvent at a concentration of 0.01 g/L.

As the photopolymerization initiator, it is also preferable to use Irgacure OXE01 (manufactured by BASF) and/or Irgacure OXE02 (manufactured by BASF) and Omnirad 2959 (manufactured by IGM Resins B.V.) in combination.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A content of the photopolymerization initiator in the total solid content of the coloring composition is preferably 0.1% to 20% by mass and more preferably 1% to 10% by mass. The lower limit is preferably 1.5% by mass or more, more preferably 2% by mass or more, and still more preferably 2.5% by mass or more. The upper limit is preferably 9% by mass or less, more preferably 8% by mass or less, and still more preferably 5% by mass or less.

In addition, it is preferable that the coloring composition contains 15 to 100 parts by mass of the photopolymerization initiator with respect to 100 parts by mass of the polymerizable compound. The upper limit is preferably 80 parts by mass or less and more preferably 70 parts by mass or less. The lower limit is preferably 25 parts by mass or more and more preferably 33 parts by mass or more.

In the coloring composition according to the embodiment of the present invention, the photopolymerization initiator may be used alone or in combination of two or more kinds thereof. In a case where two or more kinds thereof are used, the total amount thereof is preferably within the above-described range.

### <<Ultraviolet Absorber>>

The coloring composition according to the embodiment of the present invention contains an ultraviolet absorber. The ultraviolet absorber in the present specification means an organic compound having an ultraviolet absorbing function, which is a compound different from a photopolymerization initiator efficiently generating active species such as radicals, in a case of being irradiated with ultraviolet rays. The ultraviolet absorber is preferably a compound having an action of absorbing ultraviolet rays, converting the ultraviolet rays into heat energy or the like, and diverging the heat energy or the like. In addition, the ultraviolet absorber is preferably a compound which is stable against the ultraviolet rays. That is, the ultraviolet absorber is preferably a compound which is less likely to be broken in molecules due to reactions such as decomposition, oxidation, and reduction by irradiation with ultraviolet rays.

The ultraviolet absorber is preferably a compound having a maximal absorption wavelength in a wavelength range of 340 to 420 nm, more preferably a compound having a maximal absorption wavelength in a wavelength range of 345 to 400 nm, and still more preferably a compound having a maximal absorption wavelength in a wavelength range of 350 to 390 nm. In addition, the maximum value of a molar absorption coefficient of the ultraviolet absorber in the wavelength range of 340 to 420 nm is preferably 5,000 L•mol⁻¹•cm⁻¹ or more, more preferably 10,000 L•mol⁻¹•cm⁻¹ or more, and still more preferably 13,000 L•mol⁻¹•cm⁻¹ or more. The upper limit is preferably, for example, 100,000 L•mol⁻¹•cm⁻¹ or less.

In addition, in the ultraviolet absorber, a value of a ratio of an absorbance A₂ at a wavelength of 410 nm to an absorbance A₁ at a wavelength of 365 nm is preferably 0.06 or less, more preferably 0.04 or less, and still more preferably 0.02 or less.

Examples of the ultraviolet absorber include a conjugated diene compound, a benzotriazole compound, a dibenzoyl compound, a triazine compound, a benzophenone compound, a salicylate compound, a coumarin compound, an acrylonitrile compound, a benzodithiazole compound, a cinnamic acid compound, α-β unsaturated ketone, a carbostyril compound, and a merocyanine compound, and from the reason that it is possible to achieve a high level of both the improvement of illuminance dependence of sensitivity and the temporal stability of the coloring composition, a benzotriazole compound, a dibenzoyl compound, or a triazine compound is preferable.

The conjugated diene compound is preferably a compound represented by Formula (UV-1).

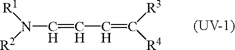

In Formula (UV-1), R¹ and R² each independently represent a hydrogen atom, an alkyl group having 1 to 20 carbon atoms, or an aryl group having 6 to 20 carbon atoms, and R¹ and R² may be the same or different from each other. However, at least one of R¹ or R² is an alkyl group having 1 to 20 carbon atoms or an aryl group having 6 to 20 carbon atoms. R¹ and R² may form a cyclic amino group together with a nitrogen atom to which R¹ and R² are bonded. Examples of the cyclic amino group include a piperidino group, a morpholino group, a pyrrolidino group, a hexahydroazepino group, and a piperazino group. R¹ and R² each independently preferably an alkyl group having 1 to 20 carbon atoms, more preferably an alkyl group having 1 to 10 carbon atoms, and still more preferably an alkyl group having 1 to 5 carbon atoms.

In Formula (UV-1), R³ and R⁴ each independently represent an electron withdrawing group. R³ and R⁴ are each independently preferably an acyl group, a carbamoyl group, an alkyloxycarbonyl group, an aryloxycarbonyl group, a cyano group, a nitro group, an alkylsulfonyl group, an arylsulfonyl group, a sulfonyloxy group, or a sulfamoyl group, and more preferably an acyl group, a carbamoyl group, an alkyloxycarbonyl group, an aryloxycarbonyl group, a cyano group, an alkylsulfonyl group, an arylsulfonyl group, a sulfonyloxy group, or a sulfamoyl group. In addition, R³ and R⁴ may be bonded to each other to form a cyclic electron withdrawing group. Examples of the cyclic electron withdrawing group formed by bonding R³ and R⁴ to each other include a 6-membered ring including two carbonyl groups.

At least one of R¹, R², R³, or R⁴ in Formula (UV-1) may be in a form of a polymer derived from a monomer bonded to a vinyl group through a linking group. Alternatively, it may be a copolymer with another monomer.

With regard to the ultraviolet absorber represented by Formula (UV-1), reference can be made to the description in paragraph Nos. 0024 to 0033 of JP2009-265642A, the content of which is incorporated herein by reference. Specific examples of the ultraviolet absorber represented by Formula (UV-1) include compounds having the following structures and compounds described in paragraph Nos. 0034 to 0036 of JP2009-265642A. In addition, examples of a commercially available product of the ultraviolet absorber represented by Formula (UV-1) include UV-503 (manufactured by Daito Chemical Co., Ltd.).

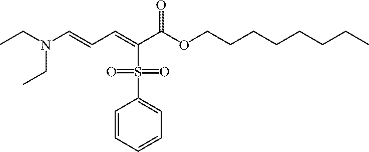 [SMILES: CCCCCCCCOC(=O)/C(=C/C=C/N(CC)CC)S(=O)(=O)c1ccccc1]

The dibenzoyl compound is preferably a compound represented by Formula (UV-2).

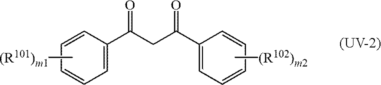

In Formula (UV-2), R¹⁰¹ and R¹⁰² each independently represent a substituent, and ml and m2 each independently represent an integer of 0 to 4.

Examples of the substituent represented by R¹⁰¹ and R¹⁰² include a halogen atom, a cyano group, a nitro group, an alkyl group, an aryl group, a heteroaryl group, an alkoxy group, an aryloxy group, a heteroaryloxy group, an alkylthio group, an arylthio group, a heteroarylthio group, -NR^{U1}R^{U2}, -COR^{U3}, -COOR^{U4}, -OCOR^{U5}, -NHCOR^{U6}, -CONR^{U7}R^{U8}, -NHCONR^{U9}R^{U10}, -NHCOOR^{U11}, -SO,R^{U12}, -SO₂OR^{U13}, -NHSO₂R^{U14}, and -SO₂NR^{U15}R^{U16}. R^{U1} to R^{U16} each independently represent a hydrogen atom, an alkyl group having 1 to 8 carbon atoms, or an aryl group.

It is preferable that the substituents represented by R¹⁰¹ and R¹⁰² are each independently an alkyl group or an alkoxy group. The number of carbon atoms in the alkyl group is preferably 1 to 20 and more preferably 1 to 10. Examples of the alkyl group include a linear alkyl group, a branched alkyl group, and a cyclic alkyl group, and a linear alkyl group or a branched alkyl group is preferable and a branched alkyl group is more preferable. The number of carbon atoms in the alkoxy group is preferably 1 to 20 and more preferably 1 to 10. The alkoxy group is preferably linear or branched, and more preferably branched.

In Formula (UV-2), a combination in which one of R¹⁰¹ or R¹⁰² is an alkyl group and the other is an alkoxy group is preferable.

ml and m2 each independently represent an integer of 0 to 4. ml and m2 are each independently preferably 0 to 2, more preferably 0 or 1, and particularly preferably 1.

Specific examples of the dibenzoyl compound include avobenzone. In addition, examples of a commercially available product of the dibenzoyl compound include Neo Heliopan 357 (manufactured by Symrise).

The triazine compound is preferably a compound represented by Formula (UV-3-1), Formula (UV-3-2), or Formula (UV-3-3).

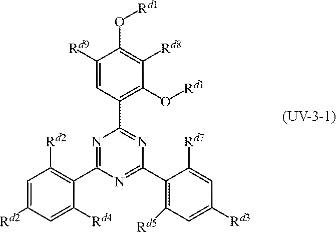

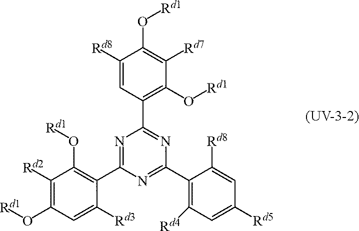

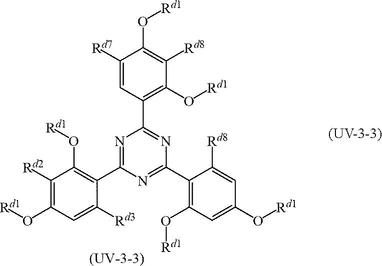

In the formulae, R^{d1}′s each independently represent a hydrogen atom, an alkyl group having 1 to 15 carbon atoms, an alkenyl group having 3 to 8 carbon atoms, an aryl group having 6 to 18 carbon atoms, an alkylaryl group having 7 to 18 carbon atoms, or an arylalkyl group having 7 to 18 carbon atoms. The alkyl group, alkenyl group, aryl group, alkylaryl group, and arylalkyl group may have a substituent. Examples of the substituent include groups described in a substituent Ti below.

In the formulae, R^{d2} to R^{d9} each independently represent a hydrogen atom, a halogen atom, a hydroxy group, an alkyl group having 1 to 15 carbon atoms, an alkenyl group having 3 to 8 carbon atoms, an aryl group having 6 to 18 carbon atoms, an alkylaryl group having 7 to 18 carbon atoms, or an arylalkyl group having 7 to 18 carbon atoms. The alkyl group, alkenyl group, aryl group, alkylaryl group, and arylalkyl group may have a substituent. Examples of the substituent include groups described in a substituent Ti below.

Examples of the substituent Ti include a halogen atom, a cyano group, a nitro group, a hydrocarbon group, a heterocyclic group, -ORti¹, -CORti¹, -COORti¹, -OCORti¹, -NRti¹Rti², -NHCORti¹, -CONRti¹Rti², -NHCONRti¹Rti², -NHCOORti¹, -SRti¹, -SO₂Rti¹, -SO₂ORti¹, -NHSO₂Rti¹, and -SO₂NRti¹Rti². Rti¹ and Rti² each independently represent a hydrogen atom, a hydrocarbon group, or a heterocyclic group. Rti¹ and Rti² may be bonded to each other to form a ring.

Examples of the halogen atom include a fluorine atom, a chlorine atom, a bromine atom, and an iodine atom.

Examples of the hydrocarbon group include an alkyl group, an alkenyl group, an alkynyl group, and an aryl group. The alkyl group preferably has 1 to 30 carbon atoms, more preferably has 1 to 15 carbon atoms, and still more preferably has 1 to 8 carbon atoms. The alkyl group may be linear, branched, or cyclic, and is preferably linear or branched and more preferably branched.

The alkenyl group preferably has 2 to 30 carbon atoms, more preferably has 2 to 12 carbon atoms, and particularly preferably has 2 to 8 carbon atoms. The alkenyl group may be linear, branched, or cyclic, and is preferably linear or branched.

The alkynyl group preferably has 2 to 30 carbon atoms and more preferably has 2 to 25 carbon atoms. The alkynyl group may be linear, branched, or cyclic, and is preferably linear or branched.

The aryl group preferably has 6 to 30 carbon atoms, more preferably has 6 to 20 carbon atoms, and still more preferably has 6 to 12 carbon atoms.

The heterocyclic group may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and still more preferably 3 to 12.

The hydrocarbon group and the heterocyclic group may have a substituent or may be unsubstituted. Examples of the substituent include the substituents described in the substituent Ti.

Specific examples of the triazine compound include mono(hydroxyphenyl)triazine compounds such as 2-[4-[(2-hydroxy-3-dodecyloxypropyl)oxy]-2-hydroxyphenyl]-4,6-bis(2,4-dimethylphenyl)-1, 3,5-triazine, 2-[4-[(2-hydroxy-3-tridecyloxypropyl)oxy]-2-hydroxyphenyl]-4,6-bis(2,4-dimethylphenyl)-1, 3,5-triazine, and 2-(2,4-dihydroxyphenyl)-4,6-bis(2,4-dimethylphenyl)-1,3,5-triazine; bis(hydroxyphenyl)triazine compounds such as 2,4-bis(2-hydroxy-4-propyloxyphenyl)-6-(2,4-dimethylphenyl)-1,3,5-triazine, 2,4-bis(2-hydroxy-3-methyl-4-propyloxyphenyl)-6-(4-methylphenyl)-1,3,5-triazine, and 2,4-bis(2-hydroxy-3-methyl-4-hexyloxyphenyl)-6-(2,4-dimethylphenyl)-1,3,5-triazine; and tris(hydroxyphenyl)triazine compounds such as 2,4-bis(2-hydroxy-4-butoxyphenyl)-6-(2,4-dibutoxyphenyl)-1,3,5-triazine, 2,4,6-tris(2-hydroxy-4-octyloxyphenyl)-1,3,5-triazine, and 2,4,6-tris[2-hydroxy-4-(3-butoxy-2-hydroxypropyloxy)phenyl]-1,3,5-triazine. Examples of a commercially available product of the triazine compound include TINUVIN 400, TINUVIN 405, TINUVIN 460, TINUVIN 477, TINUVIN 479 (all of which are manufactured by BASF), and KEMISORB 102 (manufactured by CHEMIPRO KASEI).

The benzotriazole compound is preferably a compound represented by Formula (UV-4).

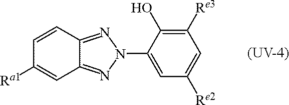

In the formula, R^{e1} to R^{e3} each independently represent a hydrogen atom, a halogen atom, a hydroxy group, an alkyl group having 1 to 9 carbon atoms, an alkoxy group having 1 to 9 carbon atoms, an alkylaryl group having 7 to 18 carbon atoms, or an arylalkyl group having 7 to 18 carbon atoms. The alkyl group, alkylaryl group, and arylalkyl group may have a substituent. Examples of the substituent include the groups described in the substituent Ti, and an alkoxycarbonyl group having 1 to 9 carbon atoms is preferable.

Specific examples of the benzotriazole compound include
2-(2′-hydroxy-3’,5′-di-tert-butylphenyl)-5-chlorobenzotriazole,
2-(2′-hydroxy-3′-tert-butyl-5′-methylphenyl)-5-chlorobenzotriazole,
2-(2′-hydroxy-3′-tert-amyl-5′-isobutylphenyl)-5-chlorobenzotriazole,
2-(2′-hydroxy-3′-isobutyl-5′-methylphenyl)-5-chlorobenzotriazole,
2-(2′-hydroxy-3′-isobutyl-5′-propylphenyl)-5-chlorobenzotriazole,
2-(2′-hydroxy-3’,5′-di-tert-butylphenyl)benzotriazole,
2-(2′-hydroxy-5′-methylphenyl)benzotriazole,
2-[2′-hydroxy-5′-(1,1,3,3-tetramethyl)phenyl]benzotriazole,
2-(2-hydroxy-5-tert-butylphenyl)-2H-benzotriazole,
3-(2H-benzotriazol-2-yl)-5-(1,1-dimethylethyl)-4-hydroxy,
2-(2H-benzotriazol-2-yl)-4,6-bis(1-methyl-1-phenylethyl)phenol, and
2-(2H-benzotriazol-2-yl)-6-(1-methyl-1-phenylethyl)-4-(1,1,3,3-tetramethylbutyl)phenol.
Examples of a commercially available product thereof include TINUVIN P, TINUVIN PS, TINUVIN 99-2, TINUVIN 109, TINUVIN 326, TINUVIN 328, TINUVIN 384-2, TINUVIN 900, TINUVIN 928, TINUVIN 171, and TINUVIN 1130 (all of which are manufactured by BASF); Sumisorb 200, Sumisorb 250, Sumisorb 300, Sumisorb 340, and Sumisorb 350 (all of which are manufactured by Sumika Chemtex Co., Ltd.); and KEMISORB 71, KEMISORB 73, KEMISORB 74, KEMISORB 79, and KEMISORB 279 (all of which are manufactured by CHEMIPRO KASEI). As the benzotriazole compound, MYUA series manufactured by Miyoshi Oil & Fat Co., Ltd. may be used.

Examples of the benzophenone compound include 2,2′-dihydroxy-4-methoxybenzophenone, 2,2′-dihydroxy-4,4′-dimethoxybenzophenone, 2,2’,4,4′-tetrahydroxybenzophenone, 2-hydroxy-4-methoxybenzophenone, 2,4-dihydroxybenzophenone, and 2-hydroxy-4-octoxybenzophenone. Examples of a commercially available product of the benzophenone compound include Uvinul A, Uvinul 049, and Uvinul 3050 (all of which are manufactured by BASF); Sumisorb 130 (manufactured by Sumika Chemtex Co., Ltd.); and KEMISORB 10, KEMISORB 11, KEMISORB 11S, KEMISORB 12, and KEMISORB 111 (all of which are manufactured by CHEMIPRO KASEI).

Examples of the salicylate compound include phenyl salicylate, p-octylphenyl salicylate, and p-t-butylphenyl salicylate.

Examples of the coumarin compound include coumarin-4, 4-hydroxycoumarin, and 7-hydroxycoumarin.

Examples of the acrylonitrile compound include ethyl 2-cyano-3,3-diphenylacrylate and 2-ethylhexyl 2-cyano-3,3-diphenylacrylate.

In addition, as the ultraviolet absorber, compounds described in paragraph Nos. 0038 to 0052 of JP2009-217221A, paragraph Nos. 0052 to 0072 of JP2012-208374A, paragraph Nos. 0317 to 0334 of JP2013-068814A, paragraph Nos. 0061 to 0080 of JP2016-162946A, paragraph Nos. 0049 to 0059 of JP6268967B, and paragraph Nos. 0059 to 0076 of WO2016/181987A can also be used.

A content of the ultraviolet absorber in the total solid content of the coloring composition is preferably 0.1% by mass or more, more preferably 0.3% by mass or more, still more preferably 0.5% by mass or more, even more preferably 1% by mass or more, and particularly preferably 1% to 10% by mass. The upper limit of the content of the ultraviolet absorber is preferably 8% by mass or less and more preferably 5% by mass or less.

In addition, it is preferable that the coloring composition contains 10 to 100 parts by mass of the ultraviolet absorber with respect to 100 parts by mass of the photopolymerization initiator. The upper limit is preferably 90 parts by mass or less and more preferably 80 parts by mass or less. The lower limit is preferably 20 parts by mass or more and more preferably 30 parts by mass or more. In a case where the proportion of the ultraviolet absorber and the photopolymerization initiator is within the above-described range, it is possible to achieve a high level of both the improvement of illuminance dependence of line width sensitivity and the temporal stability of the coloring composition.

In addition, it is preferable that the coloring composition contains 5 to 50 parts by mass of the ultraviolet absorber with respect to 100 parts by mass of the polymerizable compound. The upper limit is preferably 40 parts by mass or less and more preferably 30 parts by mass or less. The lower limit is preferably 7 parts by mass or more and more preferably 10 parts by mass or more. In a case where the proportion of the ultraviolet absorber and the polymerizable compound is within the above-described range, it is effective in improving the illuminance dependence of the line width sensitivity.

The ultraviolet absorber may be used alone or in combination of two or more kinds thereof. In a case where two or more kinds thereof are used in combination, the total thereof is within the above-described range.

### «Solvent»

The coloring composition according to the embodiment of the present invention contains a solvent. Examples of the solvent include an organic solvent. Basically, the type of the solvent is not particularly limited as long as it satisfies solubility of the respective components or coating properties of the composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, 2-pentanone, 3-pentanone, 4-heptanone, cyclohexanone, 2-methylcyclohexanone, 3-methylcyclohexanone, 4-methylcyclohexanone, cycloheptanone, cyclooctanone, cyclohexyl acetate, cyclopentanone, ethylcarbitol acetate, butylcarbitol acetate, propylene glycol monomethyl ether, propylene glycol monomethyl ether acetate, 3-methoxy-N,N-dimethylpropanamide, 3-butoxy-N,N-dimethylpropanamide, propylene glycol diacetate, 3-methoxybutanol, methyl ethyl ketone, γ-butyrolactone, sulfolane, anisole, 1,4-diacetoxybutane, diethylene glycol monoethyl ether acetate, butane diacetate-1,3-diyl, dipropylene glycol methyl ether acetate, diacetone alcohol (also known as diacetone alcohol or 4-hydroxy-4-methyl-2-pentanone), 2-methoxypropyl acetate, 2-methoxy-1-propanol, and isopropyl alcohol. In this case, the content of aromatic hydrocarbons (such as benzene, toluene, xylene, and ethylbenzene) as the organic solvent may be low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass ppb (parts per billion) or lower. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 µm or less, more preferably 5 µm or less, and still more preferably 3 µm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the coloring composition is preferably 10% to 95% by mass, more preferably 20% to 90% by mass, and still more preferably 30% to 90% by mass.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzene; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is equal to or higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, coloring composition produced by mixing these compounds, or the like.

### <<Pigment Derivative>>

The coloring composition according to the embodiment of the present invention can contain a pigment derivative. The pigment derivative is used, for example, as a dispersion aid. Examples of the pigment derivative include a compound having a structure in which an acid group or a basic group is bonded to a coloring agent skeleton.

Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton.

Examples of the acid group include a carboxy group, a sulfo group, a phosphoric acid group, a boronic acid group, a carboxylic acid amide group, a sulfonic acid amide group, an imidic acid group, and salts of these group. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. As the carboxylic acid amide group, a group represented by -NHCOR^{X1} is preferable. As the sulfonic acid amide group, a group represented by -NHSO₂R^{X2} is preferable. As the imidic acid group, a group represented by -SO₂NHSO₂R^{X3}, -CONHSO₂R^{X4}, -CONHCOR^{X5}, or -SO₂NHCOR^{X6} is preferable, and -SO₂NHSO₂R^{X3} is more preferable. R^{X1} to R^{X6} each independently represent an alkyl group or an aryl group. The alkyl group and the aryl group represented by R^{X1} to R^{X6} may have a substituent. As the substituent, a halogen atom is preferable and a fluorine atom is more preferable.

Examples of the basic group include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be used. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later; compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A; and diketopyrrolopyrrole compounds having a thiol linking group, described in WO2020/002106A.

A content of the pigment derivative is preferably 1 to 30 parts by mass, more preferably 2 to 15 parts by mass, and still more preferably 4 to 10 parts by mass with respect to 100 parts by mass of the pigment. The pigment derivative may be used alone or in combination of two or more kinds thereof. In a case where two or more kinds thereof are used in combination, the total amount thereof is preferably within the above-described range.

### <<Polyalkyleneimine>>

The coloring composition according to the embodiment of the present invention can also contain polyalkyleneimine. The polyalkyleneimine is used, for example, as a dispersion aid for the pigment. The dispersion aid is a material for increasing dispersibility of the pigment in the coloring composition. The polyalkyleneimine is a polymer obtained by a ring-opening polymerization of alkyleneimine. The polyalkyleneimine is a polymer having a branched structure including each of a primary amino group, a secondary amino group, and a tertiary amino group. The number of carbon atoms in the alkyleneimine is preferably 2 to 6, more preferably 2 to 4, still more preferably 2 or 3, and particularly preferably 2.

A molecular weight of the polyalkyleneimine is preferably 200 or more and more preferably 250 or more. The upper limit thereof is preferably 100,000 or less, more preferably 50,000 or less, still more preferably 10,000 or less, and particularly preferably 2,000 or less. With regard to the value of the molecular weight of the polyalkyleneimine, in a case where the molecular weight can be calculated from a structural formula, the molecular weight of the polyalkyleneimine is a value calculated from the structural formula. On the other hand, in a case where the molecular weight of the polyalkyleneimine cannot be calculated from the structural formula or is difficult to calculate, a value of a number-average molecular weight measured by a boiling point increase method is used. In addition, even in a case where the molecular weight of the polyalkyleneimine cannot be measured by the boiling point increase method or is difficult to be measured, a value of a number-average molecular weight measured by a viscosity method is used. In addition, in a case where the molecular weight of the polyalkyleneimine cannot be measured by the viscosity method or is difficult to be measured by the viscosity method, a value of a number-average molecular weight in terms of polystyrene through measurement by a gel permeation chromatography (GPC) method is used.

An amine value of the polyalkyleneimine is preferably 5 mmol/g or more, more preferably 10 mmol/g or more, and still more preferably 15 mmol/g or more.

Specific examples of the alkyleneimine include ethyleneimine, propyleneimine, 1,2-butyleneimine, and 2,3-butyleneimine, and ethyleneimine or propyleneimine is preferable and ethyleneimine is more preferable. The polyalkyleneimine is particularly preferably polyethyleneimine. In addition, the polyethyleneimine preferably includes the primary amino group in an amount of 10 mol% or more, more preferably includes the primary amino group in an amount of 20 mol% or more, and still more preferably includes the primary amino group in an amount of 30 mol% or more with respect to the total of the primary amino group, the secondary amino group, and the tertiary amino group. Examples of a commercially available product of the polyethyleneimine include EPOMIN SP-003, SP-006, SP-012, SP-018, SP-200, and P-1000 (all of which are manufactured by NIPPON SHOKUBAI CO., LTD.).

A content of the polyalkyleneimine in the total solid content of the coloring composition is preferably 0.1% to 5% by mass. The lower limit is preferably 0.2% by mass or more, more preferably 0.5% by mass or more, and still more preferably 1% by mass or more. The upper limit is preferably 4.5% by mass or less, more preferably 4% by mass or less, and still more preferably 3% by mass or less. In addition, the content of the polyalkyleneimine is preferably 0.5 to 20 parts by mass with respect to 100 parts by mass of the pigment. The lower limit is preferably 0.6 parts by mass or more, more preferably 1 part by mass or more, and still more preferably 2 parts by mass or more. The upper limit is preferably 10 parts by mass or less and more preferably 8 parts by mass or less. The polyalkyleneimine may be used alone or in combination of two or more kinds thereof. In a case where two or more kinds thereof are used, the total amount thereof is preferably within the above-described range.

### <<Curing Accelerator>>

The coloring composition according to the embodiment of the present invention can contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 0080 of JP2012-150180A, alkoxysilane compounds having an epoxy group described in JP2011-253054A, compounds described in paragraph Nos. 0085 to 0092 of JP5765059B, and carboxy group-containing epoxy curing agent described in JP2017-036379A. A content of the curing accelerator in the total solid content of the coloring composition is preferably 0.3% to 8.9% by mass and more preferably 0.8% to 6.4% by mass.

### <<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the coloring composition is preferably 0.0001% to 5% by mass. The polymerization inhibitor may be used alone or in combination of two or more kinds thereof. In a case of two or more kinds thereof, the total amount thereof is preferably within the above-described range.

### <<Silane Coupling Agent>>

The coloring composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference. A content of the silane coupling agent in the total solid content of the coloring composition is preferably 0.01% to 15.0% by mass and more preferably 0.05% to 10.0% by mass. The silane coupling agent may be used alone or in combination of two or more kinds thereof. In a case of two or more kinds thereof, the total amount thereof is preferably within the above-described range.

### <<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. The surfactant is preferably a silicone-based surfactant or a fluorine-based surfactant. With regard to the surfactant, surfactants described in paragraph Nos. 0238 to 0245 of WO2015/166779A can be referred to, the contents of which are incorporated herein by reference.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, surfactants described in paragraph Nos. 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-01, R-40, R-40-LM, R-41, R-41-LM, RS-43, R-43, TF-1956, RS-90, R-94, RS-72-K, and DS-21 (all of which are manufactured by DIC Corporation); FLUORAD FC430, FC431, and FC171 (all of which are manufactured by Sumitomo 3 M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215 M, 245F, 601AD, 601ADH2, 602A, 610FM, 710FL, 710FM, 710FS, and FTX-218 (manufactured by NEOS COMPANY LIMITED).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

It is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

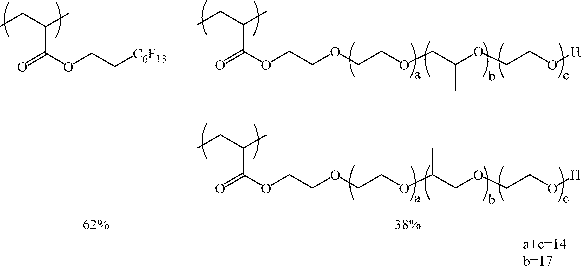

A weight-average molecular weight of the compound is preferably 3,000 to 50,000 and, for example, 14,000. In the compound, “%” representing the proportion of a repeating unit is mol%.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

In addition, from the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

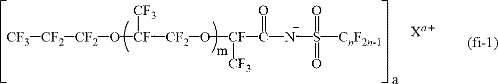

In Formula (fi-1), m represents 1 or 2, n represents an integer of 1 to 4, a represents 1 or 2, and x^{a+} represents an a-valent metal ion, a primary ammonium ion, a secondary ammonium ion, a tertiary ammonium ion, a quaternary ammonium ion, or NH₄⁺.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include DOWSIL SH8400, SH 8400 FLUID, FZ-2122, 67 Additive, 74 Additive, M Additive, and SF 8419 OIL (all of which are manufactured by Dow·TORAY); TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-333, BYK-3760, and BYK-UV3510 (all of which are manufactured by BYK-Chemie).

In addition, as the silicone-based surfactant, a compound having the following structure can also be used.

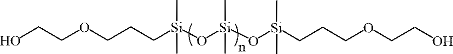

A content of the surfactant in the total solid content of the coloring composition is preferably 0.001% by mass to 5.0% by mass and more preferably 0.005% to 3.0% by mass. The surfactant may be used alone or in combination of two or more kinds thereof. In a case of two or more kinds thereof, the total amount thereof is preferably within the above-described range.

### <<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl ]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraph Nos. 0023 to 0048 of JP6268967B, compounds described in WO2017/006600A, compounds described in WO2017/164024A, or compounds described in KR10-2019-0059371A can also be used. A content of the antioxidant in the total solid content of the coloring composition is preferably 0.01% to 20% by mass and more preferably 0.3% to 15% by mass. The antioxidant may be used alone or in combination of two or more kinds thereof. In a case of using two or more kinds thereof, the total amount thereof is preferably within the above-described range.

### <<Other Components>>

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

In order to adjust the refractive index of a film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The coloring composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

It is also preferable that the coloring composition according to the embodiment of the present invention does not substantially contain terephthalic acid ester. Here, the “does not substantially contain” means that the content of terephthalic acid ester is 1000 mass ppb or less in the total amount of the coloring composition, and it is more preferable to be 100 mass ppb or less and particularly preferable to be 0.

From the viewpoint of environmental regulation, the use of perfluoroalkyl sulfonic acid and a salt thereof and use of perfluoroalkyl carboxylic acid and a salt thereof may be restricted. In the coloring composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably 0.05 ppb to 500 ppb, and still more preferably 0.1 ppb to 300 ppb with respect to the total solid content of the coloring composition. The coloring composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a coloring composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The coloring composition according to the embodiment of the present invention may include the perfluoroalkyl sulfonic acid and a salt thereof and the perfluoroalkyl carboxylic acid and a salt thereof within the maximum allowable range.

The moisture content in the coloring composition according to the embodiment of the present invention is usually 3% by mass or less, preferably 0.01% to 1.5% by mass and more preferably in a range of 0.1% to 1.0% by mass. The moisture content can be measured by a Karl Fischer method.

The coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a cone plate-type viscometer.

### <<Storage Container>>

A storage container for the coloring composition is not particularly limited, and a known storage container can be used. In addition, as the storage container, it is also preferable to use a multilayer bottle having a container interior wall constituted with six layers from six kinds of resins or a bottle having a 7-layer structure from 6 kinds of resins for the purpose of suppressing infiltration of impurities into raw materials or coloring compositions. Examples of such a container include the containers described in JP2015-123351A. In addition, for the purpose of preventing metal elution from the container interior wall, improving storage stability of the coloring composition, and suppressing the alteration of components, it is also preferable that the container interior wall is formed of glass, stainless steel, or the like.

### Method of Preparing Coloring Composition

The coloring composition according to the embodiment of the present invention can be prepared by mixing the above-described components with each other. In the preparation of the coloring composition, all the components may be dissolved and/or dispersed at the same time in a solvent to prepare the coloring composition, or the respective components may be appropriately left in two or more solutions or dispersion liquids and mixed to prepare the coloring composition upon use (during coating), as desired.

In addition, in the preparation of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include a fluororesin such as polytetrafluoroethylene (PTFE) and polyvinylidene fluoride (PVDF); a polyamide-based resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 µm, more preferably 0.01 to 3.0 µm, and still more preferably 0.05 to 0.5 µm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed. In addition, the filter can be appropriately selected according to hydrophilicity or hydrophobicity of the composition.

### Film

A film according to an embodiment of the present invention is a film obtained from the above-described coloring composition according to the embodiment of the present invention. The film according to the embodiment of the present invention can be used for a color filter or the like. Specifically, the film according to the embodiment of the present invention can be preferably used as a colored layer (pixel) of a color filter, and more preferably used as a cyan pixel. A film thickness of the film according to the embodiment of the present invention can be adjusted according to the purpose, and is preferably 0.1 to 20 µm. The upper limit of the film thickness is preferably 10 µm or less, more preferably 5 µm or less, still more preferably 3 µm or less, and particularly preferably 1.5 µm or less. The lower limit of the film thickness is preferably 0.2 µm or more and more preferably 0.3 µm or more.

In the film according to the embodiment of the present invention, an average value of transmittance of light in a wavelength range of 400 to 450 nm is preferably 75% or more, more preferably 80% or more, and still more preferably 85% or more. The upper limit can be 100% or less.

In addition, in the film according to the embodiment of the present invention, an average value of transmittance of light in a wavelength range of 650 to 700 nm is preferably 30% or less, more preferably 25% or less, and still more preferably 20% or less. The lower limit can be 0% or more.

In addition, in the film according to the embodiment of the present invention, a wavelength of light, at which a transmittance is 50%, preferably exists in a wavelength range of 560 to 590 nm, more preferably exists in a wavelength range of 565 to 585 nm, and still more preferably exists in a wavelength range of 570 to 580 nm.

### Method for Forming Pixel

A method for forming a pixel will be described. A cyan pixel can be formed of, for example, the coloring composition according to the embodiment of the present invention.

The method for forming a pixel preferably includes a step of forming a coloring composition layer by applying a coloring composition to a support, a step of exposing the coloring composition layer in a patterned manner, and a step of developing the coloring composition layer after exposure.

In the step of forming a coloring composition layer, the coloring composition is applied onto a support to form the coloring composition layer. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of substances, or planarize the surface of the substrate. The base layer may be formed of a composition obtained by removing a colorant from the coloring composition described in the present specification, a composition containing the resin, polymerizable compound, surfactant, and the like described in the present specification, or the like. A surface contact angle of the base layer is preferably 20° to 70° in a case of being measured with diiodomethane. In addition, the surface contact angle of the base layer is preferably 30° to 80° in a case of being measured with water.

As a method of applying the coloring composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet -Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the coloring composition layer may be irradiated with light continuously to expose the coloring composition layer, or the coloring composition layer may be irradiated with light in a pulse to expose the coloring composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

### Color Filter

The color filter according to the embodiment of the present invention has the above-described film according to the embodiment of the present invention. The color filter according to the embodiment of the present invention has the film according to the embodiment of the present invention preferably as a colored pixel of the color filter, and more preferably as a cyan pixel of the color filter. The color filter according to the embodiment of the present invention can be used in a solid-state imaging element, an image display device, or the like.

It is preferable that the color filter according to the embodiment of the present invention has a colored pixel having another hue in addition to the pixel of the film according to the embodiment of the present invention. Examples of the colored pixel having another hue include a blue pixel, a red pixel, a yellow pixel, and a magenta pixel. Examples of a preferred aspect of the color filter according to the embodiment of the present invention include an aspect of having a cyan pixel composed of the film according to the embodiment of the present invention, a yellow pixel, and a magenta pixel. The color filter may have a structure in which each colored pixel is embedded in a space partitioned in, for example, a lattice form by a partition wall. In this case, it is preferable that the partition wall has a lower refractive index than each colored pixel. In addition, the partition wall may be formed with a configuration described in US2018/0040656A.

In the color filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 µm and more preferably 0.1 to 5 µm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

### Solid-State Imaging Element

A solid-state imaging element according to an embodiment of the present invention has the film according to the embodiment of the present invention. The configuration of the solid-state imaging element is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. In this case, it is preferable that the partition wall has a lower refractive index than each colored pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

### Image Display Device

The film according to the embodiment of the present invention can also be used in an image display device. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like.

In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

### Production of Dispersion Liquid

A mixed solution obtained by mixing materials shown in the following table was mixed and dispersed for 3 hours using a beads mill (zirconia beads having a diameter of 0.1 mm). Next, using a high-pressure disperser NANO-3000-10 (manufactured by Nippon BEE Chemical Co., Ltd.) equipped with a pressure reducing mechanism, the dispersion liquid was dispersed under a pressure of 2,000 kg/cm³ at a flow rate of 500 g/min. The dispersion treatment was repeated a total of 10 times to obtain a dispersion liquid. In the following table, the unit of the numerical value described in the column of the blending amount is part by mass.

TABLE 1

| | Colorant | | Dispersant 1 | | Dispersant 2 | | Solvent | |
|---|---|---|---|---|---|---|---|---|
| | Type | Blending amount | Type | Blending amount | Type | Blending amount | Type | Blending amount |
| Dispersion liquid 1 | PB15:4 | 13.0 | A-1 | 2.0 | A-2 | 4.50 | Z-1 | 80.5 |
| Dispersion liquid 2 | PG7 | 13.0 | A-1 | 5.2 | A-2 | 1.30 | Z-1 | 80.5 |
| Dispersion liquid 3 | PG36 | 13.0 | A-1 | 1.50 | A-2 | 5.00 | Z-1 | 80.5 |
| Dispersion liquid 4 | PB15:6 | 13.0 | A-1 | 2.0 | A-2 | 4.50 | Z-1 | 80.5 |
| Dispersion liquid 5 | PG7 | 13.0 | A-3 | 5.2 | A-2 | 1.30 | Z-1 | 80.5 |
| Dispersion liquid 6 | PG7 | 13.0 | A-4 | 5.2 | A-2 | 1.30 | Z-1 | 80.5 |
| Dispersion liquid 7 | PG7 | 13.0 | A-5 | 5.2 | A-2 | 1.30 | Z-1 | 80.5 |
| Dispersion liquid 8 | PG7 | 13.0 | A-6 | 5.2 | A-2 | 1.30 | Z-1 | 80.5 |
| Dispersion liquid 9 | PG7 | 13.0 | A-7 | 5.2 | A-2 | 1.30 | Z-1 | 80.5 |

Materials described by abbreviations shown in the above table are as follows.

### (Colorant)

PG7: C. I. Pigment Green 7 (halogenated copper phthalocyanine pigment)
PG36: C. I. Pigment Green 36 (halogenated copper phthalocyanine pigment)
PB15:4: C. I. Pigment Blue 15:4 (unsubstituted copper phthalocyanine pigment)
PB15:6: C. I. Pigment Blue 15:6 (unsubstituted copper phthalocyanine pigment)

### (Dispersant)

A-1: resin having the following structure (the numerical value described together with the main chain indicates a molar ratio; weight-average molecular weight: 11,000)

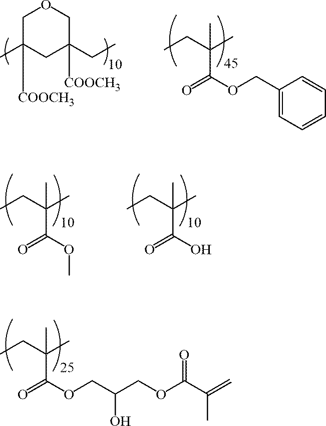

A-2: resin having the following structure (the numerical value described together with the main chain indicates a molar ratio, and the numerical value described together with the side chain indicates the number of repeating units; weight-average molecular weight: 24,000)

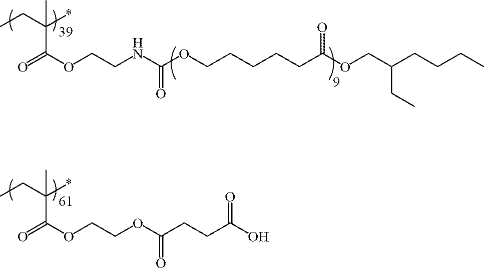

A-3: resin synthesized by the following method

An appropriate amount of nitrogen was flowed into a flask equipped with a reflux condenser, a dropping funnel, and a stirrer to replace the atmosphere with nitrogen, and 340 parts by mass of propylene glycol monomethyl ether acetate (PGMEA) was added thereto and heated to 80° C. while stirring. Next, a mixed solution of 57 parts by mass of acrylic acid, 54 parts by mass of a mixture of 3,4-epoxytricyclo[5.2.1.0^{2,6}]decan-8-yl acrylate and 3,4-epoxytricyclo[5.2.1.0^{2,6}]decan-9-yl acrylate(content ratio was 1:1 in molar ratio), 239 parts by mass of benzyl methacrylate, and 73 parts by mass of PGMEA was added dropwise thereto over 5 hours. Next, a solution prepared by dissolving 40 parts by mass of a polymerization initiator (2,2-azobis(2,4-dimethylvaleronitrile)) in 197 parts by mass of PGMEA was added dropwise thereto over 6 hours. After completion of the dropwise addition of the polymerization initiator solution, the mixture was kept at 80° C. for 3 hours and then cooled to room temperature to obtain a resin having the following structure. The obtained resin had a weight-average molecular weight of 9,400, a dispersibility of 1.89, and an acid value of 114 mgKOH/g.

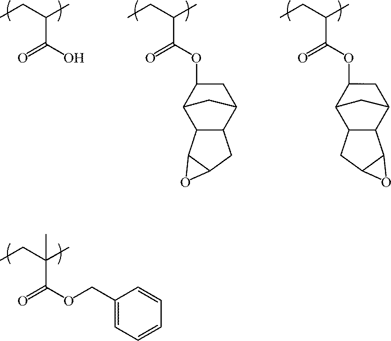

A-4: resin having the following structure (the numerical value described together with the main chain indicates a molar ratio, and the numerical value described together with the side chain indicates the number of repeating units; weight-average molecular weight: 20,000)

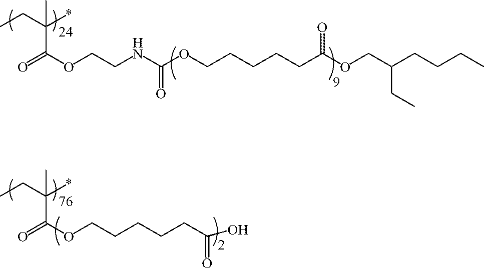

A-5: resin having the following structure (the numerical value described together with the main chain indicates a molar ratio, and the numerical value described together with the side chain indicates the number of repeating units; weight-average molecular weight: 16,000)

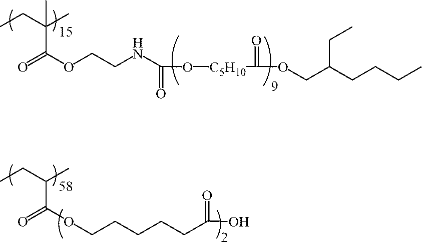

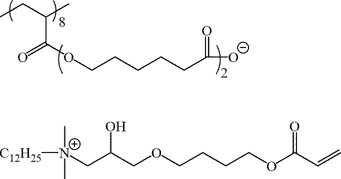

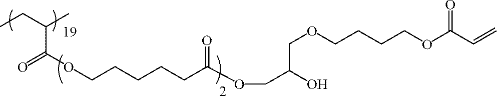

A-6: resin having the following structure (the numerical value described together with the main chain indicates a molar ratio, and the numerical value described together with the side chain indicates the number of repeating units; weight-average molecular weight: 20,000)

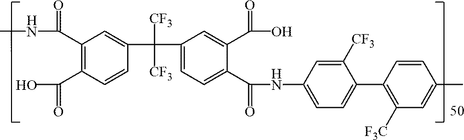

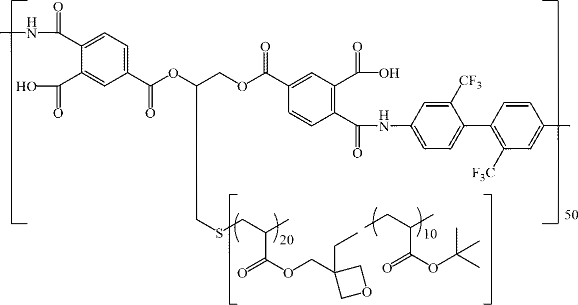

A-7: resin having the following structure (the numerical value described together with the main chain indicates a molar ratio, and the numerical value described together with the side chain indicates the number of repeating units; weight-average molecular weight: 7,000)

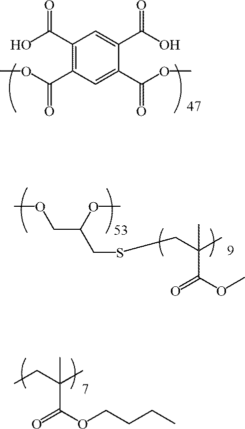

### (Solvent)

Z-1: propylene glycol monomethyl ether acetate (PGMEA)

### Production of Coloring Composition

Raw materials described in the following tables were mixed to produce a coloring composition. In the following table, the unit of the numerical value described in the column of the blending amount is part by mass.

TABLE 2

| | Dispersion liquid | | | | | | Binder | | Photopolymerization initiator | | Monomer | |
|---|---|---|---|---|---|---|---|---|---|---|---|---|
| | Type | Blending amount | Type | Blending amount | Type | Blending amount | Type | Blending amount | Type | Blending amount | Type | Blending amount |
| Example 1 | Dispersion liquid 1 | 11.0 | Dispersion liquid 2 | 17.8 | - | - | B-1 | 8.7 | C-1 | 0.5 | D-1 | 2.7 |
| Example 2 | Dispersion liquid 1 | 8.9 | Dispersion liquid 2 | 14.3 | - | - | B-1 | 14.3 | C-1 | 0.5 | D-1 | 2.7 |
| Example 3 | Dispersion liquid 1 | 4.30 | Dispersion liquid 2 | 17.7 | Dispersion liquid 3 | 6.80 | B-1 | 8.7 | C-1 | 0.5 | D-1 | 2.7 |
| Example 4 | Dispersion liquid 1 | 3.00 | Dispersion liquid 2 | 25.8 | - | - | B-1 | 8.7 | C-1 | 0.5 | D-1 | 2.7 |
| Example 5 | Dispersion liquid 1 | 5.70 | Dispersion liquid 2 | 23.1 | - | - | B-1 | 8.7 | C-1 | 0.5 | D-1 | 2.7 |
| Example 6 | Dispersion liquid 1 | 7.50 | Dispersion liquid 2 | 21.3 | - | - | B-1 | 8.7 | C-1 | 0.5 | D-1 | 2.7 |
| Example 7 | Dispersion liquid 1 | 9.10 | Dispersion liquid 2 | 19.7 | - | - | B-1 | 8.7 | C-1 | 0.5 | D-1 | 2.7 |
| Example 8 | Dispersion liquid 1 | 13.20 | Dispersion liquid 2 | 15.6 | - | - | B-1 | 8.7 | C-1 | 0.5 | D-1 | 2.7 |
| Example 9 | Dispersion liquid 1 | 14.40 | Dispersion liquid 2 | 14.4 | - | - | B-1 | 8.7 | C-1 | 0.5 | D-1 | 2.7 |
| Example 10 | Dispersion liquid 1 | 17.20 | Dispersion liquid 2 | 11.6 | - | - | B-1 | 8.7 | C-1 | 0.5 | D-1 | 2.7 |
| Example 11 | Dispersion liquid 1 | 11.0 | Dispersion liquid 2 | 17.8 | - | - | B-1 | 8.8 | C-1 | 0.5 | D-1 | 2.8 |
| Example 12 | Dispersion liquid 1 | 11.0 | Dispersion liquid 2 | 17.8 | - | - | B-1 | 8.8 | C-1 | 0.6 | D-1 | 2.8 |
| Example 13 | Dispersion liquid 1 | 11.0 | Dispersion liquid 2 | 17.8 | - | - | B-1 | 4.0 | C-1 | 1.8 | D-1 | 6.1 |
| Example 14 | Dispersion liquid 1 | 11.0 | Dispersion liquid 2 | 17.8 | - | - | B-1 | 9.0 | C-1 | 0.3 | D-1 | 2.9 |
| Example 15 | Dispersion liquid 4 | 11.0 | Dispersion liquid 2 | 17.8 | - | - | B-1 | 8.7 | C-1 | 0.5 | D-1 | 2.7 |
| Example 16 | Dispersion liquid 1 | 11.0 | Dispersion liquid 5 | 17.8 | - | - | B-1 | 8.7 | C-1 | 0.5 | D-1 | 2.7 |
| Example 17 | Dispersion liquid 1 | 11.0 | Dispersion liquid 6 | 17.8 | - | - | B-1 | 8.7 | C-1 | 0.5 | D-1 | 2.7 |
| Example 18 | Dispersion liquid 1 | 11.0 | Dispersion liquid 7 | 17.8 | - | - | B-1 | 8.7 | C-1 | 0.5 | D-1 | 2.7 |
| Example 19 | Dispersion liquid 1 | 11.0 | Dispersion liquid 8 | 17.8 | - | - | B-1 | 8.7 | C-1 | 0.5 | D-1 | 2.7 |
| Example 20 | Dispersion liquid 1 | 11.0 | Dispersion liquid 9 | 17.8 | - | - | B-1 | 8.7 | C-1 | 0.5 | D-1 | 2.7 |
| Example 21 | Dispersion liquid 1 | 11.0 | Dispersion liquid 2 | 17.8 | - | - | B-2 | 8.7 | C-1 | 0.5 | D-1 | 2.7 |
| Example 22 | Dispersion liquid 1 | 11.0 | Dispersion liquid 2 | 17.8 | - | - | B-3 | 8.7 | C-1 | 0.5 | D-1 | 2.7 |
| Example 23 | Dispersion liquid 1 | 11.0 | Dispersion liquid 2 | 17.8 | - | - | B-4 | 8.7 | C-1 | 0.5 | D-1 | 2.7 |
| Example 24 | Dispersion liquid 1 | 11.0 | Dispersion liquid 2 | 17.8 | - | - | B-5 | 8.7 | C-1 | 0.5 | D-1 | 2.7 |
| Example 25 | Dispersion liquid 1 | 11.0 | Dispersion liquid 2 | 17.8 | - | - | B-1 | 8.7 | C-2 | 0.5 | D-1 | 2.7 |
| Example 26 | Dispersion liquid 1 | 11.0 | Dispersion liquid 2 | 17.8 | - | - | B-1 | 8.7 | C-3 | 0.5 | D-1 | 2.7 |
| Example 27 | Dispersion liquid 1 | 11.0 | Dispersion liquid 2 | 17.8 | - | - | B-1 | 8.7 | C-4 | 0.5 | D-1 | 2.7 |
| Example 28 | Dispersion liquid 1 | 11.0 | Dispersion liquid 2 | 17.8 | - | - | B-1 | 8.7 | C-5 | 0.5 | D-1 | 2.7 |
| Example 29 | Dispersion liquid 1 | 11.0 | Dispersion liquid 2 | 17.8 | - | - | B-1 | 8.7 | C-1 | 0.5 | D-2 | 2.7 |
| Example 30 | Dispersion liquid 1 | 11.0 | Dispersion liquid 2 | 17.8 | - | - | B-1 | 8.7 | C-1 | 0.5 | D-3 | 2.7 |

TABLE 3

| | Ultraviolet absorber | | Surfactant | | Polymerization inhibitor | | Additive | | Solvent | |
|---|---|---|---|---|---|---|---|---|---|---|
| | Type | Blending amount | Type | Blending amount | Type | Blending amount | Type | Blending amount | Type | Blending amount |
| Example 1 | E-1 | 0.35 | F-1 | 0.04 | G-1 | 0.001 | - | - | Z-1 | 58.9 |
| Example 2 | E-1 | 0.40 | F-1 | 0.04 | G-1 | 0.001 | - | - | Z-1 | 58.9 |
| Example 3 | E-1 | 0.40 | F-1 | 0.04 | G-1 | 0.001 | - | - | Z-1 | 58.9 |
| Example 4 | E-1 | 0.40 | F-1 | 0.04 | G-1 | 0.001 | - | - | Z-1 | 58.9 |
| Example 5 | E-1 | 0.40 | F-1 | 0.04 | G-1 | 0.001 | - | - | Z-1 | 58.9 |
| Example 6 | E-1 | 0.40 | F-1 | 0.04 | G-1 | 0.001 | - | - | Z-1 | 58.9 |
| Example 7 | E-1 | 0.40 | F-1 | 0.04 | G-1 | 0.001 | - | - | Z-1 | 58.9 |
| Example 8 | E-1 | 0.40 | F-1 | 0.04 | G-1 | 0.001 | - | - | Z-1 | 58.9 |
| Example 9 | E-1 | 0.40 | F-1 | 0.04 | G-1 | 0.001 | - | - | Z-1 | 58.9 |
| Example 10 | E-1 | 0.40 | F-1 | 0.04 | G-1 | 0.001 | - | - | Z-1 | 58.9 |
| Example 11 | E-1 | 0.20 | F-1 | 0.04 | G-1 | 0.001 | - | - | Z-1 | 58.9 |
| Example 12 | E-1 | 0.05 | F-1 | 0.04 | G-1 | 0.001 | - | - | Z-1 | 58.9 |
| Example 13 | E-1 | 0.35 | F-1 | 0.04 | G-1 | 0.001 | - | - | Z-1 | 58.9 |
| Example 14 | E-1 | 0.10 | F-1 | 0.04 | G-1 | 0.001 | - | - | Z-1 | 58.9 |
| Example 15 | E-1 | 0.35 | F-1 | 0.04 | G-1 | 0.001 | - | - | Z-1 | 58.9 |
| Example 16 | E-1 | 0.35 | F-1 | 0.04 | G-1 | 0.001 | - | - | Z-1 | 58.9 |
| Example 17 | E-1 | 0.35 | F-1 | 0.04 | G-1 | 0.001 | - | - | Z-1 | 58.9 |
| Example 18 | E-1 | 0.35 | F-1 | 0.04 | G-1 | 0.001 | - | - | Z-1 | 58.9 |
| Example 19 | E-1 | 0.35 | F-1 | 0.04 | G-1 | 0.001 | - | - | Z-1 | 58.9 |
| Example 20 | E-1 | 0.35 | F-1 | 0.04 | G-1 | 0.001 | - | - | Z-1 | 58.9 |
| Example 21 | E-1 | 0.35 | F-1 | 0.04 | G-1 | 0.001 | - | - | Z-1 | 58.9 |
| Example 22 | E-1 | 0.35 | F-1 | 0.04 | G-1 | 0.001 | - | - | Z-1 | 58.9 |
| Example 23 | E-1 | 0.35 | F-1 | 0.04 | G-1 | 0.001 | - | - | Z-1 | 58.9 |
| Example 24 | E-1 | 0.35 | F-1 | 0.04 | G-1 | 0.001 | - | - | Z-1 | 58.9 |
| Example 25 | E-1 | 0.35 | F-1 | 0.04 | G-1 | 0.001 | - | - | Z-1 | 58.9 |
| Example 26 | E-1 | 0.35 | F-1 | 0.04 | G-1 | 0.001 | - | - | Z-1 | 58.9 |
| Example 27 | E-1 | 0.35 | F-1 | 0.04 | G-1 | 0.001 | - | - | Z-1 | 58.9 |
| Example 28 | E-1 | 0.35 | F-1 | 0.04 | G-1 | 0.001 | - | - | Z-1 | 58.9 |
| Example 29 | E-1 | 0.35 | F-1 | 0.04 | G-1 | 0.001 | - | - | Z-1 | 58.9 |
| Example 30 | E-1 | 0.35 | F-1 | 0.04 | G-1 | 0.001 | - | - | Z-1 | 58.9 |

TABLE 4

| | Dispersion liquid | | | | | | Binder | | Photopolymerization initiator | | Monomer | |
|---|---|---|---|---|---|---|---|---|---|---|---|---|
| | Type | Blending amount | Type | Blending amount | Type | Blending amount | Type | Blending amount | Type | Blending amount | Type | Blending amount |
| Example 31 | Dispersion liquid 1 | 11.0 | Dispersion liquid 2 | 17.8 | - | - | B-1 | 8.7 | C-1 | 0.5 | D-4 | 2.7 |
| Example 32 | Dispersion liquid 1 | 11.0 | Dispersion liquid 2 | 17.8 | - | - | B-1 | 8.7 | C-1 | 0.5 | D-5 | 2.7 |
| Example 33 | Dispersion liquid 1 | 11.0 | Dispersion liquid 2 | 17.8 | - | - | B-1 | 8.7 | C-1 | 0.5 | D-6 | 2.7 |
| Example 34 | Dispersion liquid 1 | 11.0 | Dispersion liquid 2 | 17.8 | - | - | B-1 | 8.7 | C-1 | 0.5 | D-1 | 2.7 |
| Example 35 | Dispersion liquid 1 | 11.0 | Dispersion liquid 2 | 17.8 | - | - | B-1 | 8.7 | C-1 | 0.5 | D-1 | 2.7 |
| Example 36 | Dispersion liquid 1 | 11.0 | Dispersion liquid 2 | 17.8 | - | - | B-1 | 8.7 | C-1 | 0.5 | D-1 | 2.7 |
| Example 37 | Dispersion liquid 1 | 11.0 | Dispersion liquid 2 | 17.8 | - | - | B-1 | 8.7 | C-1 | 0.5 | D-1 | 2.7 |
| Example 38 | Dispersion liquid 1 | 11.0 | Dispersion liquid 2 | 17.8 | - | - | B-1 | 8.7 | C-1 | 0.5 | D-1 | 2.7 |
| Example 39 | Dispersion liquid 1 | 11.0 | Dispersion liquid 2 | 17.8 | - | - | B-1 | 8.7 | C-1 | 0.5 | D-1 | 2.7 |
| Example 40 | Dispersion liquid 1 | 11.0 | Dispersion liquid 2 | 17.8 | - | - | B-1 | 8.7 | C-1 | 0.5 | D-1 | 2.7 |
| Example 41 | Dispersion liquid 1 | 11.0 | Dispersion liquid 2 | 17.8 | - | - | B-1 | 8.2 | C-1 | 0.4 | D-1 | 2.3 |
| Example 42 | Dispersion liquid 1 | 11.0 | Dispersion liquid 2 | 17.8 | - | - | B-1 | 8.2 | C-1 | 0.4 | D-1 | 2.3 |
| Example 43 | Dispersion liquid 1 | 11.0 | Dispersion liquid 2 | 17.8 | - | - | B-1 | 8.2 | C-1 | 0.4 | D-1 | 2.3 |
| Example 44 | Dispersion liquid 1 | 11.0 | Dispersion liquid 2 | 17.8 | - | - | B-1 | 8.2 | C-1 | 0.4 | D-1 | 2.3 |
| Example 45 | Dispersion liquid 1 | 11.0 | Dispersion liquid 2 | 17.8 | - | - | B-1 | 8.2 | C-1 | 0.4 | D-1 | 2.3 |
| Example 46 | Dispersion liquid 1 | 11.0 | Dispersion liquid 2 | 17.8 | - | - | B-1 | 8.7 | C-1 | 0.5 | D-1 | 2.7 |
| Example 47 | Dispersion liquid 1 | 11.0 | Dispersion liquid 2 | 17.8 | - | - | B-1 | 8.7 | C-1 | 0.5 | D-1 | 2.7 |
| Example 48 | Dispersion liquid 1 | 11.0 | Dispersion liquid 2 | 17.8 | - | - | B-1 | 8.7 | C-1 | 0.5 | D-1 | 2.7 |
| Example 49 | Dispersion liquid 1 | 11.0 | Dispersion liquid 2 | 17.8 | - | - | B-1 | 8.7 | C-1 | 0.5 | D-1 | 2.7 |
| Example 50 | Dispersion liquid 1 | 11.0 | Dispersion liquid 2 | 17.8 | - | - | B-1 | 8.7 | C-1 | 0.5 | D-1 | 2.7 |
| Example 51 | Dispersion liquid 1 | 11.0 | Dispersion liquid 2 | 17.8 | - | - | B-1 | 8.7 | C-1 | 0.5 | D-1 | 2.7 |
| Comparative Example 1 | Dispersion liquid 1 | 11.0 | Dispersion liquid 2 | 17.8 | - | - | B-1 | 8.9 | C-1 | 0.6 | D-1 | 2.8 |
| Comparative Example 2 | Dispersion liquid 1 | 11.0 | Dispersion liquid 2 | 17.8 | - | - | B-1 | 9.1 | C-1 | 0.2 | D-1 | 3.0 |
| Comparative Example 3 | Dispersion liquid 1 | 18.0 | Dispersion liquid 2 | 10.8 | - | - | B-1 | 8.7 | C-1 | 0.5 | D-1 | 2.7 |

TABLE 5

| | Ultraviolet absorber | | Surfactant | | Polymerization inhibitor | | Additive | | Solvent | |
|---|---|---|---|---|---|---|---|---|---|---|
| | Type | Blending amount | Type | Blending amount | Type | Blending amount | Type | Blending amount | Type | Blending amount |
| Example 31 | E-1 | 0.35 | F-1 | 0.04 | G-1 | 0.001 | - | - | Z-1 | 58.9 |
| Example 32 | E-1 | 0.35 | F-1 | 0.04 | G-1 | 0.001 | - | - | Z-1 | 58.9 |
| Example 33 | E-1 | 0.35 | F-1 | 0.04 | G-1 | 0.001 | - | - | Z-1 | 58.9 |
| Example 34 | E-2 | 0.35 | F-1 | 0.04 | G-1 | 0.001 | - | - | Z-1 | 58.9 |
| Example 35 | E-3 | 0.35 | F-1 | 0.04 | G-1 | 0.001 | - | - | Z-1 | 58.9 |
| Example 36 | E-4 | 0.35 | F-1 | 0.04 | G-1 | 0.001 | - | - | Z-1 | 58.9 |
| Example 37 | E-5 | 0.35 | F-1 | 0.04 | G-1 | 0.001 | - | - | Z-1 | 58.9 |
| Example 38 | E-6 | 0.35 | F-1 | 0.04 | G-1 | 0.001 | - | - | Z-1 | 58.9 |
| Example 39 | E-1 | 0.35 | F-2 | 0.04 | G-1 | 0.001 | - | - | Z-1 | 58.9 |
| Example 40 | E-1 | 0.35 | F-3 | 0.04 | G-1 | 0.001 | - | - | Z-1 | 58.9 |
| Example 41 | E-1 | 0.35 | F-1 | 0.04 | G-1 | 0.001 | H-1 | 1.0 | Z-1 | 58.9 |
| Example 42 | E-1 | 0.35 | F-1 | 0.04 | G-1 | 0.001 | H-2 | 1.0 | Z-1 | 58.9 |
| Example 43 | E-1 | 0.35 | F-1 | 0.04 | G-1 | 0.001 | H-3 | 1.0 | Z-1 | 58.9 |
| Example 44 | E-1 | 0.35 | F-1 | 0.04 | G-1 | 0.001 | H-4 | 1.0 | Z-1 | 58.9 |
| Example 45 | E-1 | 0.35 | F-1 | 0.04 | G-1 | 0.001 | H-5 | 1.0 | Z-1 | 58.9 |
| Example 46 | E-1 | 0.35 | F-1 | 0.04 | G-1 | 0.001 | - | - | Z-2 | 58.9 |
| Example 47 | E-1 | 0.35 | F-1 | 0.04 | G-1 | 0.001 | - | - | Z-3 | 58.9 |
| Example 48 | E-1 | 0.35 | F-1 | 0.04 | G-1 | 0.001 | - | - | Z-4 | 58.9 |
| Example 49 | E-1 | 0.35 | F-1 | 0.04 | G-1 | 0.001 | - | - | Z-5 | 58.9 |
| Example 50 | E-1 | 0.35 | F-1 | 0.04 | G-1 | 0.001 | - | - | Z-6 | 58.9 |
| Example 51 | E-1 | 0.35 | F-1 | 0.04 | G-1 | 0.001 | - | - | Z-7 | 58.9 |
| Comparative Example 1 | - | - | F-1 | 0.04 | G-1 | 0.001 | - | - | Z-1 | 58.9 |
| Comparative Example 2 | - | - | F-1 | 0.04 | G-1 | 0.001 | - | - | Z-1 | 58.9 |
| Comparative Example 3 | E-1 | 0.40 | F-1 | 0.04 | G-1 | 0.001 | - | - | Z-1 | 58.9 |

The raw materials described by abbreviations shown in the above tables are as follows.

### (Dispersion Liquid)

Dispersion liquids 1 to 9: dispersion liquids 1 to 9 described above

### (Binder)

B-1: 40% by mass PGMEA solution of a resin having the following structure (the numerical value described together with the main chain indicates a molar ratio; weight-average molecular weight: 11,000)

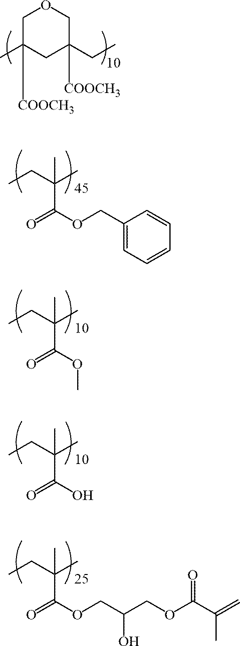

B-2: 40% by mass propylene glycol monomethyl ether acetate (PGMEA) solution of a resin synthesized by the following method

An appropriate amount of nitrogen was flowed into a flask equipped with a reflux condenser, a dropping funnel, and a stirrer to replace the atmosphere with nitrogen, and 371 parts by mass of PGMEA was added thereto and heated to 85° C. while stirring. Next, a mixed solution of 54 parts by mass of acrylic acid, 225 parts by mass of a mixture of 3,4-epoxytricyclo[5.2.1.0^{2,6}]decane-8-yl acrylate and 3,4-epoxytricyclo[5.2.1.0^{2,6}]decan-9-yl acrylate, 81 parts by mass of vinyltoluene (isomer mixture), and 80 parts by mass of PGMEA was added dropwise thereto over 4 hours. On the other hand, a solution prepared by dissolving 30 parts by mass of a polymerization initiator of 2,2-azobis(2,4-dimethylvaleronitrile) in 160 parts by mass of PGMEA was added dropwise thereto over 5 hours. After completion of the dropwise addition of the initiator solution, the mixture was kept at 85° C. for 4 hours and then cooled to room temperature to synthesize a resin. The obtained resin had a weight-average molecular weight of 10,600, a dispersibility of 2.01, and an acid value of 43 mgKOH/g. Next, PGMEA was added thereto to adjust the concentration of solid contents to 40% by mass, thereby obtaining a binder B-2.

B-3: 40% by mass PGMEA solution of a resin having the following structure (the numerical value described together with the main chain indicates a molar ratio; weight-average molecular weight: 30,000)

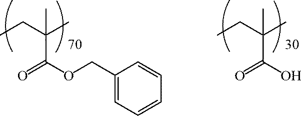

B-4: 40% by mass PGMEA solution of a resin having the following structure (the numerical value described together with the main chain indicates a mass ratio; weight-average molecular weight: 14,600)

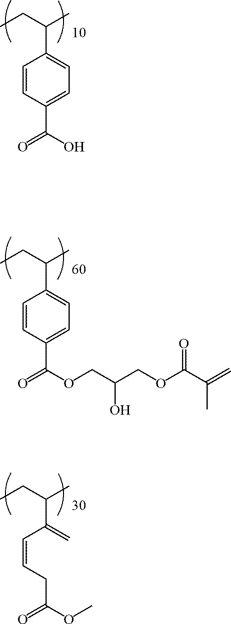

B-5: 40% by mass PGMEA solution of a resin having the following structure (the numerical value described together with the main chain indicates a mass ratio; weight-average molecular weight: 10,600)

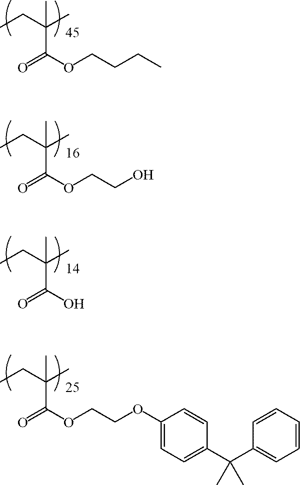

### (Photopolymerization Initiator)

C-1 to C-4: compounds having the following structures
C-5:

2,2′,4-tris(2-chlorophenyl)-5-(3,4-dimethoxyphenyl)-4,5-diphenyl-1,1′-biimidazole

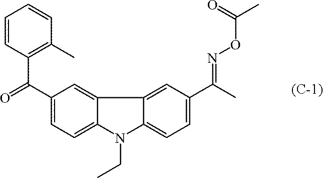 [SMILES: CCn1c2ccc(C(=O)c3ccccc3C)cc2c2cc(/C(C)=N/OC(C)=O)ccc21]

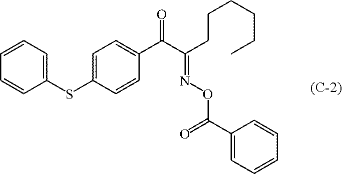 [SMILES: CCCCCC/C(=N\OC(=O)c1ccccc1)C(=O)c1ccc(Sc2ccccc2)cc1]

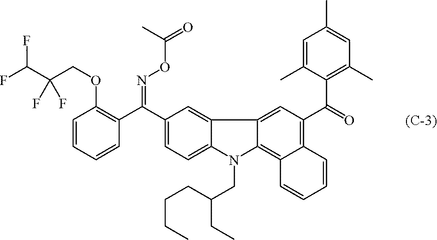 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

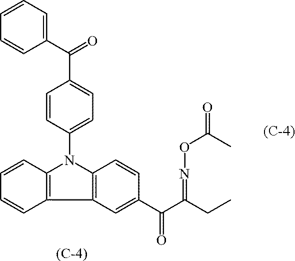 [SMILES: CCC(=NOC(C)=O)C(=O)c1ccc2c(c1)c1ccccc1n2-c1ccc(C(=O)c2ccccc2)cc1 ; "(C-4)"]

### (Monomer)

D-1: mixture of compounds having the following structures (mixture in which a molar ratio of a compound on the left (hexafunctional (meth)acrylate compound) and a compound on the right (pentafuctional (meth)acrylate compound) was 7:3)

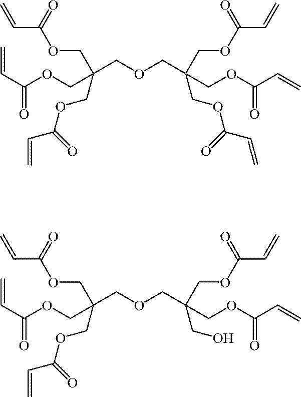

D-2: compound having the following structure

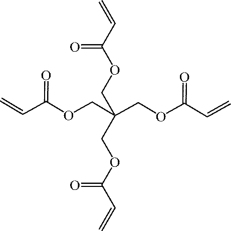 [SMILES: C=CC(=O)OCC(COC(=O)C=C)(COC(=O)C=C)COC(=O)C=C]

D-3: compound having the following structure

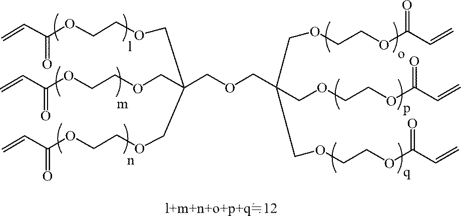

D-4: trimethylolpropane ethyleneoxide-modified triacrylate (manufactured by TOAGOSEI CO., LTD, ARONIX M-350)
D-5: EBECRYL80 (manufactured by DAICEL-ALLNEX LTD., amine-containing tetrafunctional acrylate)
D-6: ethoxylated dipentaerythritol hexamethacrylate

### (Ultraviolet Absorber)

E-1: compound having the following structure (conjugated diene compound)

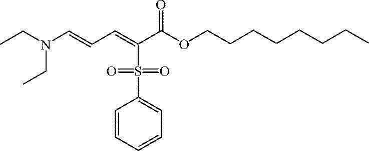 [SMILES: CCCCCCCCOC(=O)/C(=C/C=C/N(CC)CC)S(=O)(=O)c1ccccc1]

E-2: Neo Heliopan 357 (manufactured by Symrise)
E-3: TINUVIN 477 (manufactured by BASF, triazine compound)
E-4: TINUVIN P (manufactured by BASF, benzotriazole compound)
E-5: KEMISORB 10 (manufactured by CHEMIPRO KASEI, benzophenone compound)
E-6: Sumisorb 200 (manufactured by CHEMIPRO KASEI, benzotriazole compound)

### (Surfactant)

F-1: compound having the following structure (silicone-based surfactant, hydroxyl value: 62 mgKOH/g)

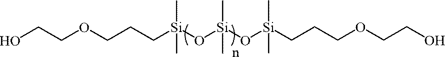

F-2: compound having the following structure (weight-average molecular weight: 14,000); in the following formula, % representing the proportion of the repeating unit is mol % (fluorine-based surfactant)

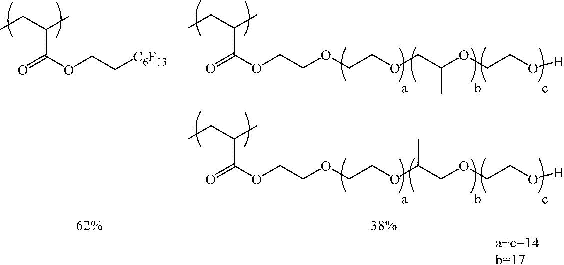

F-3: FTERGENT 208G (manufactured by NEOS COMPANY LIMITED, fluorine-based surfactant)

### (Polymerization Inhibitor)

G-1: p-methoxyphenol

### (Additive)

H-1: compound having the following structure (compound having an epoxy group, weight-average molecular weight: 3,500)

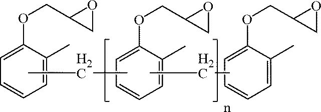

H-2: EHPE 3150 (manufactured by DAICEL-ALLNEX LTD.; 1,2-epoxy-4-(2-oxiranyl)cyclohexane adduct of 2,2′-bis(hydroxymethyl)-1-butanol)
H-3: compound having the following structure (silane coupling agent)

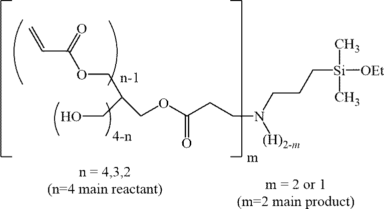

H-4: 3-methacryloxypropyltrimethoxysilane (KBM-503, manufactured by Shin-Etsu Chemical Co., Ltd., silane coupling agent)
H-5: ADK STAB AO-80 (manufactured by ADEKA Corporation, antioxidant)

### (Solvent)

Z-1: propylene glycol monomethyl ether acetate (PGMEA)
Z-2: propylene glycol monomethyl ether (PGME)
Z-3: cyclopentanone
Z-4: cyclohexanone
Z-5: anisole
Z-6: diacetone alcohol
Z-7: cyclohexanol acetate

The following tables show the ratio (mass ratio) of the unsubstituted copper phthalocyanine pigment, the ratio (mass ratio) of C. I. Pigment Green 7 (PG7) which is the halogenated copper phthalocyanine pigment, and the ratio (mass ratio) of C. I. Pigment Green 36 (PG36) which is the halogenated copper phthalocyanine pigment, which are in the colorant contained in each coloring composition. In addition, the ratio of the content of the resin with respect to the content of the colorant (resin/colorant) is described in the column of ratio of resin/colorant in the following tables. In addition, the content of the ultraviolet absorber in the total solid content of the coloring composition is described in the column of content of ultraviolet absorber. In addition, the content of the photopolymerization initiator in the total solid content of the coloring composition is described in the column of content of photopolymerization initiator.

TABLE 6

| | Ratio to all colorants | | | Ratio of resin/colorant | Content of ultraviolet absorber | Content of photopolymerization initiator |
|---|---|---|---|---|---|---|
| | Unsubstituted copper phthalocyanine pigment | PG7 | PG36 | | | |
| Example 1 | 38% | 62% | - | 143% | 2.8% | 3.9% |
| Example 2 | 38% | 62% | - | 240% | 2.9% | 3.6% |
| Example 3 | 15% | 61% | 24% | 143% | 3.1% | 3.9% |
| Example 4 | 10% | 90% | - | 143% | 3.1% | 3.9% |
| Example 5 | 20% | 80% | - | 143% | 3.1% | 3.9% |
| Example 6 | 26% | 74% | - | 143% | 3.1% | 3.9% |
| Example 7 | 32% | 68% | - | 143% | 3.1% | 3.9% |
| Example 8 | 46% | 54% | - | 143% | 3.1% | 3.9% |
| Example 9 | 50% | 50% | - | 143% | 3.1% | 3.9% |
| Example 10 | 60% | 40% | - | 143% | 3.1% | 3.9% |
| Example 11 | 38% | 62% | - | 144% | 1.6% | 3.9% |
| Example 12 | 38% | 62% | - | 144% | 0.4% | 4.8% |
| Example 13 | 38% | 62% | - | 93% | 2.3% | 11.6% |
| Example 14 | 38% | 62% | - | 146% | 0.8% | 2.4% |
| Example 15 | 38% | 62% | - | 143% | 2.8% | 3.9% |
| Example 16 | 38% | 62% | - | 143% | 2.8% | 3.9% |
| Example 17 | 38% | 62% | - | 143% | 2.8% | 3.9% |
| Example 18 | 38% | 62% | - | 143% | 2.8% | 3.9% |
| Example 19 | 38% | 62% | - | 143% | 2.8% | 3.9% |
| Example 20 | 38% | 62% | - | 143% | 2.8% | 3.9% |
| Example 21 | 38% | 62% | - | 143% | 2.8% | 3.9% |
| Example 22 | 38% | 62% | - | 143% | 2.8% | 3.9% |
| Example 23 | 38% | 62% | - | 143% | 2.8% | 3.9% |
| Example 24 | 38% | 62% | - | 143% | 2.8% | 3.9% |
| Example 25 | 38% | 62% | - | 143% | 2.8% | 3.9% |
| Example 26 | 38% | 62% | - | 143% | 2.8% | 3.9% |
| Example 27 | 38% | 62% | - | 143% | 2.8% | 3.9% |
| Example 28 | 38% | 62% | - | 143% | 2.8% | 3.9% |
| Example 29 | 38% | 62% | - | 143% | 2.8% | 3.9% |
| Example 30 | 38% | 62% | - | 143% | 2.8% | 3.9% |

TABLE 7

| | Ratio to all colorants | | | Ratio of resin/colorant | Content of ultraviolet absorber | Content of photopolymerization initiator |
|---|---|---|---|---|---|---|
| | Unsubstituted copper phthalocyanine pigment | PG7 | PG36 | | | |
| Example 31 | 38% | 62% | - | 143% | 2.8% | 3.9% |
| Example 32 | 38% | 62% | - | 143% | 2.8% | 3.9% |
| Example 33 | 38% | 62% | - | 143% | 2.8% | 3.9% |
| Example 34 | 38% | 62% | - | 143% | 2.8% | 3.9% |
| Example 35 | 38% | 62% | - | 143% | 2.8% | 3.9% |
| Example 36 | 38% | 62% | - | 143% | 2.8% | 3.9% |
| Example 37 | 38% | 62% | - | 143% | 2.8% | 3.9% |
| Example 38 | 38% | 62% | - | 143% | 2.8% | 3.9% |
| Example 39 | 38% | 62% | - | 143% | 2.8% | 3.9% |
| Example 40 | 38% | 62% | - | 143% | 2.8% | 3.9% |
| Example 41 | 38% | 62% | - | 138% | 2.7% | 3.1% |
| Example 42 | 38% | 62% | - | 138% | 2.7% | 3.1% |
| Example 43 | 38% | 62% | - | 138% | 2.7% | 3.1% |
| Example 44 | 38% | 62% | - | 138% | 2.7% | 3.1% |
| Example 45 | 38% | 62% | - | 138% | 2.7% | 3.1% |
| Example 46 | 38% | 62% | - | 143% | 2.8% | 3.9% |
| Example 47 | 38% | 62% | - | 143% | 2.8% | 3.9% |
| Example 48 | 38% | 62% | - | 143% | 2.8% | 3.9% |
| Example 49 | 38% | 62% | - | 143% | 2.8% | 3.9% |
| Example 50 | 38% | 62% | - | 143% | 2.8% | 3.9% |
| Example 51 | 38% | 62% | - | 143% | 2.8% | 3.9% |
| Comparative Example 1 | 38% | 62% | - | 145% | 0.0% | 4.8% |
| Comparative Example 2 | 38% | 62% | - | 147% | 0.0% | 1.6% |
| Comparative Example 3 | 63% | 38% | - | 143% | 3.1% | 3.9% |

### Evaluation of Spectral Characteristics

The coloring composition was applied onto a glass substrate according to a spin coating method, subjected to a heating treatment (pre-baking) for 120 seconds using a hot plate at 100° C., exposed with i-rays at an exposure amount of 1000 mJ/cm², and then heated at 200° C. for 5 minutes to produce a film having a thickness of 0.6 µm. With regard to the obtained film, using a spectroscope (manufactured by OTSUKA ELECTRONICS CO., LTD., MCPD-3000), light transmittance (transmittance) in a wavelength range of 400 to 700 nm was measured, an average value (T1) of transmittance of light in a wavelength range of 400 to 450 nm, an average value (T2) of transmittance of light in a wavelength range of 650 to 700 nm, and a wavelength (λ50) at which a transmittance was 50% were obtained respectively, and spectral characteristics were evaluated according to the following standard.

-Average value (T1) of transmittance of light in wavelength range of 400 to 450 nm-
A: T1 was 85% or more.
B: T1 was 80% or more and less than 85%.
C: T1 was 75% or more and less than 80%.
D: T1 was less than 75%.

-Average value (T2) of transmittance of light in wavelength range of 650 to 700 nm-
A: T2 was 20% or less.
B: T2 was more than 20% and 25% or less.
C: T2 was more than 25% and 30% or less.
D: T2 was more than 30%.

-Wavelength (λ50) at which transmittance was 50%-
A: λ50 existed in a wavelength range of 570 nm or more and 580 nm or less.
B: λ50 existed in a wavelength range of 565 nm or more and less than 570 nm, or in a wavelength range of more than 580 nm and 585 nm or less.
C: λ50 existed in a wavelength range of 560 nm or more and less than 565 nm, or in a wavelength range of more than 585 nm and 590 nm or less.
D: λ50 existed in a wavelength range of less than 560 nm or in a wavelength range of more than 590 nm.

### Evaluation of Illuminance Dependence of Line Width

The coloring composition was applied onto a silicon wafer according to a spin coating method, and subjected to a heating treatment (pre-baking) for 120 seconds using a hot plate at 100° C. to form a composition layer having a thickness of 0.6 µm. Next, using an i-ray stepper exposure device FPA-3000 i5+ (manufactured by Canon Inc.), the composition layer was irradiated with light having a wavelength of 365 nm through a mask in which square non-masked portions with a side length of 1.0 µm were arranged in an area of 4 mm × 3 mm to perform exposure thereon with an exposure illuminance of 6,000 W/m² and an exposure amount of 500 mJ/cm². Next, the silicon wafer on which the composition layer after the exposure had been formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pattern (pixel) to manufacture a substrate with pixels. Next, the pixels on the substrate were divided, a cross section was vapor-deposited with platinum, and using a scanning electron microscope (manufactured by Hitachi High-Tech Corporation), a cross-sectional scanning electron microscope (SEM) image was obtained. Five pixels were extracted from the cross-sectional SEM image, and an average value of line widths of the five pixels was obtained.

Pixels were formed in the same manner as described above, except that the exposure illuminance during exposure was changed to 10,000 W/m², 20,000 W/m², or 30,000 W/m², and a substrate with pixels was manufactured. The pixels on each substrate were divided, and a cross-sectional SEM image was obtained in the same manner as described above. Thereafter, five pixels were extracted from the cross-sectional SEM image, and an average value of line widths of the five pixels was obtained.

A substrate with pixels, which was created by exposure under a condition of an exposure illuminance of 6,000 W/m², was defined as A1, a substrate with pixels, which was created by exposure under a condition of an exposure illuminance of 10,000 W/m², was defined as A2, a substrate with pixels, which was created by exposure under a condition of an exposure illuminance of 20,000 W/m², was defined as A3, and a substrate with pixels, which was created by exposure under a condition of an exposure illuminance of 30,000 W/m², was defined as A4.

A standard deviation σ of the average value of the line widths of the pixels in A1 to A4 was obtained, and illuminance dependence of the line width was evaluated based on the following standard.
A: standard deviation σ was less than 0.3 µm.
B: standard deviation σ was 0.3 µm or more and less than 0.5 µm.
C: standard deviation σ was 0.5 µm or more and less than 0.7 µm.
D: standard deviation σ was 0.7 µm or more.

### Evaluation of Temporal Stability of Sensitivity

The coloring composition was applied onto a silicon wafer according to a spin coating method, and subjected to a heating treatment (pre-baking) for 120 seconds using a hot plate at 100° C. to form a composition layer having a thickness of 0.6 µm. As the coloring composition, a coloring composition immediately after the production or a coloring composition after storage in a constant-temperature tank at 5° C. for 12 months was used. In addition, the temperature of each coloring composition was adjusted to 23° C. for use.

Next, using an i-ray stepper exposure device FPA-3000 i5+ (manufactured by Canon Inc.), the composition layer was irradiated with light having a wavelength of 365 nm through a mask in which square non-masked portions with a side length of 1.0 µm were arranged in an area of 4 mm × 3 mm to perform exposure thereon with an exposure illuminance of 10,000 W/m² and an exposure amount of 500 mJ/cm². Next, the silicon wafer on which the composition layer after the exposure had been formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pixel to manufacture a substrate with pixels. Next, the pixels on the substrate were divided, a cross section was vapor-deposited with platinum, and using a scanning electron microscope (manufactured by Hitachi High-Tech Corporation), a cross-sectional SEM image was obtained. Five pixels were extracted from the cross-sectional SEM image, and an average value of line widths of the five pixels was obtained.

A rate of change in line width was calculated from the following expression, and temporal stability of the sensitivity was evaluated.

$$\begin{matrix}\text{Rate} \text{of} \text{change} \text{in} \text{line} \text{width} \left(\%\right) = \\ \left(\left(\text{Average} \text{value} \text{2} \text{of} \text{line} \text{width} / \text{Average} \text{value} \text{1} \text{of} \text{line} \text{width}\right) \text{-} 1\right) \times \\ 100\end{matrix}$$

The average value 1 of the line width is an average value of the line widths of the pixels formed of the coloring composition immediately after the production, and the average value 2 of the line width is an average value of the line widths of the pixels formed of the coloring composition after storage in a constant-temperature tank at 5° C. for 12 months.
A: rate of change in line width was less than 5.0%.
B: rate of change in line width was 5.0% or more and less than 7.5%.
C: rate of change in line width was 7.5% or more and less than 10.0%.
D: rate of change in line width was 10.0% or more.

### Evaluation of Light Resistance

The coloring composition was applied onto a glass substrate according to a spin coating method, subjected to a heating treatment (pre-baking) for 120 seconds using a hot plate at 100° C., exposed with i-rays at an exposure amount of 1000 mJ/cm², and then heated at 200° C. for 5 minutes to produce a film having a thickness of 0.6 µm. Light transmittance (transmittance) of the obtained film in a wavelength range of 400 to 700 nm was measured by using a spectroscope (manufactured by OTSUKA ELECTRONICS CO., LTD., MCPD-3000). Next, the film produced above was irradiated with light of 100,000 Lux over 2,000 hours (total irradiation amount: 200 million Lux·hr) using a light resistance tester (Super Xenon Weather Meter SX75, manufactured by Suga Test Instruments Co., Ltd.). The transmittance of the film after light irradiation was measured, and light resistance was evaluated based on the following standard.

A: integrated value of the transmittance of the film after light irradiation at a wavelength of 400 to 700 nm was 98% or more of the integrated value of the transmittance of the film before light irradiation at a wavelength of 400 to 700 nm.

B: integrated value of the transmittance of the film after light irradiation at a wavelength of 400 to 700 nm was 94% or more and less than 98% of the integrated value of the transmittance of the film before light irradiation at a wavelength of 400 to 700 nm.

C: integrated value of the transmittance of the film after light irradiation at a wavelength of 400 to 700 nm was 90% or more and less than 94% of the integrated value of the transmittance of the film before light irradiation at a wavelength of 400 to 700 nm.

D: integrated value of the transmittance of the film after light irradiation at a wavelength of 400 to 700 nm was less than 90% of the integrated value of the transmittance of the film before light irradiation at a wavelength of 400 to 700 nm.

TABLE 8

| | Spectroscopy | | | Illuminance dependence of line width | Temporal stability of sensitivity | Light resistance |
|---|---|---|---|---|---|---|
| | T1 | T2 | λ50 | | | |
| Example 1 | B | A | B | A | A | B |
| Example 2 | A | A | B | A | A | B |
| Example 3 | B | B | A | A | A | A |
| Example 4 | C | C | A | A | A | C |
| Example 5 | C | B | B | A | A | C |
| Example 6 | C | B | B | A | A | B |
| Example 7 | B | B | B | A | A | B |
| Example 8 | B | A | C | A | A | A |
| Example 9 | B | A | C | A | A | A |
| Example 10 | A | A | C | A | A | A |
| Example 11 | B | A | B | B | A | B |
| Example 12 | B | A | B | C | A | B |
| Example 13 | B | A | B | B | A | B |
| Example 14 | B | A | B | B | C | B |
| Example 15 | C | A | B | A | A | B |
| Example 16 | B | A | B | A | A | A |
| Example 17 | B | A | B | A | A | B |
| Example 18 | B | A | B | A | A | B |
| Example 19 | B | A | B | A | A | B |
| Example 20 | B | A | B | A | A | B |
| Example 21 | B | A | B | A | A | A |
| Example 22 | B | A | B | A | A | B |
| Example 23 | B | A | B | A | A | B |
| Example 24 | B | A | B | A | A | B |
| Example 25 | B | A | B | A | A | B |
| Example 26 | B | A | B | A | A | B |
| Example 27 | B | A | B | A | A | B |
| Example 28 | B | A | B | A | A | B |
| Example 29 | B | A | B | A | A | B |
| Example 30 | B | A | B | A | A | B |

TABLE 9

| | Spectroscopy | | | Illuminance dependence of line width | Temporal stability of sensitivity | Light resistance |
|---|---|---|---|---|---|---|
| | T1 | T2 | λ50 | | | |
| Example 31 | B | A | B | A | A | B |
| Example 32 | B | A | B | A | A | B |
| Example 33 | B | A | B | A | A | B |
| Example 34 | B | A | B | A | A | B |
| Example 35 | B | A | B | A | A | B |
| Example 36 | B | A | B | A | A | B |
| Example 37 | B | A | B | B | A | B |
| Example 38 | B | A | B | A | A | B |
| Example 39 | B | A | B | A | A | B |
| Example 40 | B | A | B | A | A | B |
| Example 41 | B | A | B | A | A | B |
| Example 42 | B | A | B | A | A | B |
| Example 43 | B | A | B | A | A | B |
| Example 44 | B | A | B | A | A | B |
| Example 45 | B | A | B | A | A | B |
| Example 46 | B | A | B | A | A | B |
| Example 47 | B | A | B | A | A | B |
| Example 48 | B | A | B | A | A | B |
| Example 49 | B | A | B | A | A | B |
| Example 50 | B | A | B | A | A | B |
| Example 51 | B | A | B | A | A | B |
| Comparative Example 1 | A | A | A | D | A | B |
| Comparative Example 2 | A | A | A | C | D | B |
| Comparative Example 3 | A | A | D | D | A | A |

As shown in the above tables, in the coloring compositions of Examples, the evaluation results of the illuminance dependence of the line width and the temporal stability of the sensitivity were both evaluation results of A to C, indicating that the illuminance dependence of the line width was small and the temporal stability of the sensitivity was excellent. In addition, by using the coloring compositions of Examples, a film having excellent light resistance could be formed. The same results were obtained in a case where no surfactant was added in Example 1. The same results were obtained in a case where no polymerization inhibitor was added in Example 1.

### (Example 1001)

A silicon wafer was coated with the coloring composition of Example 1 by a spin coating method so that a film thickness of a film after film formation was 0.6 µm. Next, the silicon wafer was heated using a hot plate at 100° C. for 2 minutes. Next, using an i-ray stepper exposure device FPA-3000 i5+ (manufactured by Canon Inc.), exposure was performed with light having an exposure amount of 1000 mJ/cm² through a mask having a dot pattern of 1 µm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the coloring composition was patterned by heating at 200° C. for 5 minutes using a hot plate to form a cyan pixel. In the same process, a red coloring composition and a yellow coloring composition were patterned to sequentially form a red pixel and a yellow pixel, thereby forming a color filter having the cyan pixel, red pixel, and yellow pixel. The red coloring composition and yellow coloring composition will be described later. In this color filter, the yellow pixel was formed in a Bayer pattern, and the red pixel and cyan pixel were formed in an island pattern in an adjacent region thereof. The obtained color filter was incorporated into a solid-state imaging element according to a known method. The solid-state imaging element had a suitable image recognition ability.

### (Red Coloring Composition)

The following components were mixed and stirred, and the obtained mixture was filtered through a nylon filter (manufactured by Nihon Pall Corporation) having a pore size of 0.45 µm to prepare the red coloring composition.

| | |
|---|---|
| Red pigment dispersion liquid | ··· 51.7 parts by mass |
| Resin 101 | ··· 0.6 parts by mass |
| Polymerizable compound (NK ESTER A-DPH-12E, manufactured by | |
| Shin-Nakamura Chemical Co., Ltd.) | ··· 0.6 parts by mass |
| Photopolymerization initiator (Irgacure OXE01, manufactured by BASF) | |
| | ··· 0.4 parts by mass |
| Surfactant 101 | ··· 4.2 parts by mass |
| Ultraviolet absorber (UV-503, manufactured by Daito Chemical Co., Ltd.) | |
| | ··· 0.3 parts by mass |
| PGMEA | ··· 42.6 parts by mass |

### (Yellow Coloring Composition)

The following components were mixed and stirred, and the obtained mixture was filtered through a nylon filter (manufactured by Nihon Pall Corporation) having a pore size of 0.45 µm to prepare the blue coloring composition.

| | |
|---|---|
| Yellow pigment dispersion liquid | ··· 44.9 parts by mass |
| Resin 101 | ··· 2.1 parts by mass |
| Polymerizable compound (KAYARAD DPHA, manufactured by Nippon Kayaku Co., | |
| Ltd.) | ··· 1.5 parts by mass |
| Polymerizable compound (NK ESTER A-DPH-12E, manufactured by | |
| Shin-Nakamura Chemical Co., Ltd.) | ··· 0.7 parts by mass |
| Photopolymerization initiator (Irgacure OXE01, manufactured by BASF) | |
| | ··· 0.8 parts by mass |
| Surfactant 101 | ··· 4.2 parts by mass |
| Ultraviolet absorber (UV-503, manufactured by Daito Chemical Co., Ltd.) | |
| | ··· 0.3 parts by mass |
| PGMEA | ··· 45.8 parts by mass |

The materials used for the red coloring composition and the yellow coloring composition are as follows.

### · Red Pigment Dispersion Liquid

A mixed solution consisting of 9.6 parts by mass of C. I. Pigment Red 254, 4.3 parts by mass of C. I. Pigment Yellow 139, 6.8 parts by mass of a dispersant (Disperbyk-161, manufactured by BYK-Chemie), and 79.3 parts by mass of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times, thereby obtaining the red pigment dispersion liquid.

### · Yellow Pigment Dispersion Liquid

A mixed solution consisting of 12.1 parts by mass of C. I. Pigment Yellow 150, 5.5 parts by mass of a dispersant (Disperbyk-161, manufactured by BYK-Chemie), and 82.4 parts by mass of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times, thereby obtaining the yellow pigment dispersion liquid.

· Resin 101: resin having the following structure (acid value: 70 mgKOH/g, Mw = 11000; a ratio in a structural unit is a molar ratio)

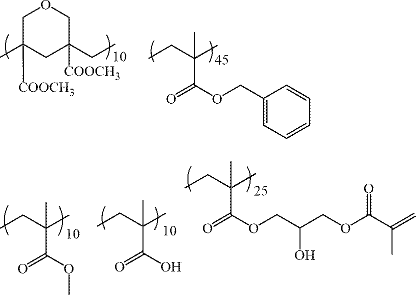

· Surfactant 101: 1% by mass PGMEA solution of a compound having the following structure (weight-average molecular weight: 14,000; in the following formula, % representing the proportion of the repeating unit is mol%)

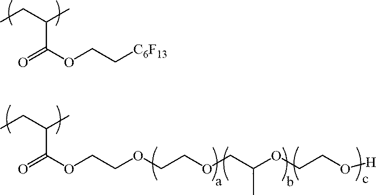

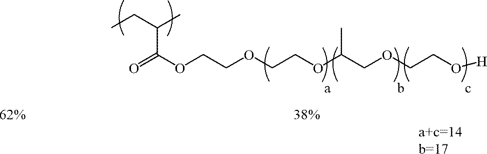

### (Example 1002)

A color filter was formed by the same method as in Example 1001, except that the red coloring composition of Example 1001 was changed to the following magenta coloring composition to create a magenta pixel. The obtained color filter was incorporated into a solid-state imaging element according to a known method. The solid-state imaging element had a suitable image recognition ability.

### (Magenta Coloring Composition)

The following components were mixed and stirred, and the obtained mixture was filtered through a nylon filter (manufactured by Nihon Pall Corporation) having a pore size of 0.45 µm to prepare a magenta coloring composition.

| | |
|---|---|
| Magenta pigment dispersion liquid | ··· 44.9 parts by mass |
| Resin 101 | ··· 2.1 parts by mass |
| Polymerizable compound (KAYARAD DPHA, manufactured by Nippon Kayaku Co., | |
| Ltd.) | ··· 1.5 parts by mass |
| Polymerizable compound (NK ESTER A-DPH-12E, manufactured by | |
| Shin-Nakamura Chemical Co., Ltd.) | ··· 0.7 parts by mass |
| Photopolymerization initiator (Irgacure OXE01, manufactured by BASF) | |
| | ··· 0.8 parts by mass |
| Surfactant 101 | ··· 4.2 parts by mass |
| Ultraviolet absorber (UV-503, manufactured by Daito Chemical Co., Ltd.) | |
| | ··· 0.3 parts by mass |
| PGMEA | ··· 45.8 parts by mass |

### · Magenta Pigment Dispersion Liquid 1

A mixed solution consisting of 12.1 parts by mass of C. I. Pigment Red 122, 5.5 parts by mass of a dispersant (Disperbyk-161, manufactured by BYK-Chemie), and 82.4 parts by mass of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times, thereby obtaining the magenta pigment dispersion liquid.

What is claimed is:

1. A coloring composition comprising:
a colorant;
a resin;
a polymerizable compound;
a photopolymerization initiator;
an ultraviolet absorber; and
a solvent,
wherein the colorant contains an unsubstituted copper phthalocyanine pigment and a halogenated copper phthalocyanine pigment,
a content of the unsubstituted copper phthalocyanine pigment in a total mass of the colorant is 10% by mass or more, and
a content of the halogenated copper phthalocyanine pigment in the total mass of the colorant is 40% by mass or more.

2. The coloring composition according to claim 1,
wherein the unsubstituted copper phthalocyanine pigment includes Color Index Pigment Blue 15:4, and
the halogenated copper phthalocyanine pigment includes Color Index Pigment Green 7.

3. The coloring composition according to claim 1,
wherein a total content of the unsubstituted copper phthalocyanine pigment and the halogenated copper phthalocyanine pigment in the total mass of the colorant is 70% to 100% by mass.

4. The coloring composition according to claim 1,
wherein, in a case where a film having a film thickness of 0.6 µm is formed of the coloring composition, an average value of transmittance of light in a wavelength range of 400 to 450 nm in a thickness direction of the film is 75% or more, an average value of transmittance of light in a wavelength range of 650 to 700 nm in the thickness direction of the film is 30% or less, and a wavelength at which a transmittance is 50% exists in a wavelength range of 560 to 590 nm.

5. A coloring composition comprising:
a colorant;
a resin;
a polymerizable compound;
a photopolymerization initiator;
an ultraviolet absorber; and
a solvent,
wherein, in a case where a film having a film thickness of 0.6 µm is formed of the coloring composition, an average value of transmittance of light in a wavelength range of 400 to 450 nm in a thickness direction of the film is 75% or more, an average value of transmittance of light in a wavelength range of 650 to 700 nm in the thickness direction of the film is 30% or less, and a wavelength at which a transmittance is 50% exists in a wavelength range of 560 to 590 nm.

6. The coloring composition according to claim 1,
wherein a content of the ultraviolet absorber in a total solid content of the coloring composition is 0.5% by mass or more.

7. The coloring composition according to claim 1,
wherein, in the ultraviolet absorber, a value of a ratio of an absorbance A₂ at a wavelength of 410 nm to an absorbance A₁ at a wavelength of 365 nm is 0.06 or less.

8. The coloring composition according to claim 1,
wherein the ultraviolet absorber is at least one selected from a conjugated diene compound, a benzotriazole compound, a dibenzoyl compound, or a triazine compound.

9. The coloring composition according to claim 1,
wherein the coloring composition contains 100 to 350 parts by mass of the resin with respect to 100 parts by mass of the colorant.

10. The coloring composition according to claim 1,
wherein the resin includes a resin having at least one repeating unit selected from a repeating unit represented by Formula (1) or a repeating unit represented by Formula (2), 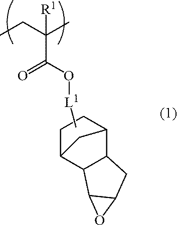 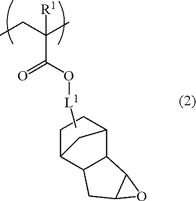
in the formulae, L¹ represents a single bond or a divalent linking group, and R¹ represents a hydrogen atom or a substituent.

11. The coloring composition according to claim 1,
wherein a content of Color Index Pigment Blue 15:4 in the total mass of the colorant is 10% to 50% by mass,
a content of the photopolymerization initiator in a total solid content of the coloring composition is 3% to 10% by mass, and
a content of the ultraviolet absorber in the total solid content of the coloring composition is 1% to 10% by mass.

12. A film obtained from the coloring composition according to claim 1.

13. A color filter comprising:
the film according to claim 12.

14. A solid-state imaging element comprising:
the film according to claim 12.
